(19) United States
(12) Patent Application Publication
(10) Pub. No.: US 2026/0036897 A1
(43) Pub. Date: Feb. 5, 2026

(54) REPAIR PROCESS FOR CLEAR DEFECTS ON EUV PSM MASKS

(71) Applicant: Carl Zeiss SMT GmbH, Oberkochen (DE)

(72) Inventors: Christian Rensing, Bensheim (DE); Michael Brendel, Aschaffenburg (DE); Gerson Mette, Hoesbach (DE); Fan Tu, Dieburg (DE); Christian Felix Hermanns, Frankfurt (DE); Nicole Auth, Gustavsburg (DE)

(21) Appl. No.: 19/357,330

(22) Filed: Oct. 14, 2025

Related U.S. Application Data
(63) Continuation of application No. PCT/EP2024/061028, filed on Apr. 23, 2024.

(30) Foreign Application Priority Data
Apr. 25, 2023 (DE) 102023203821.8

(51) Int. Cl. G03F 1/22; G03F 7/00; H01J 37/317

(52) U.S. Cl. CPC G03F 1/22; G03F 7/70033; G03F 7/70625; G03F 7/70666; G03F 7/706847; H01J 37/3178

(57) ABSTRACT

The present disclosure relates to a method of processing a phase-shift mask for EUV lithography, comprising: particle beam-induced depositing of a repair material using a precursor gas for repair of an imaging structure of the mask. According to the disclosure, the imaging structure can be repaired in such a way that at least one critical dimension of the mask has a deviation from a predetermined critical dimension of at least below 15%, preferably below 10%, more preferably below 5%, most preferably below 3%.

The present disclosure further relates to a phase-shift mask for EUV lithography, to a computer program and to a device.

### CROSS-REFERENCE TO RELATED APPLICATIONS

This application is a continuation of and claims benefit under 35 U.S.C. § 120 from PCT Application No. PCT/EP2024/061028, filed on Apr. 23, 2024, which claims priority from German Application No. 10 2023 203 821.8, filed on Apr. 25, 2023. The entire contents of each of these earlier applications are incorporated herein by reference.

### TECHNICAL FIELD

The present invention relates to a method, to a phase-shift mask for EUV lithography, to a computer program and to a device for processing a phase-shift mask for EUV lithography. In particular, the present invention relates to particle beam-induced deposition of a repair material using a precursor gas.

### BACKGROUND

In the semiconductor industry, increasingly smaller structures are produced on a wafer in order to ensure an increase in integration density. Among the methods used here for the production of the structures are lithography methods which image these structures onto the wafer. The lithography methods may include, for example, photolithography, ultraviolet (UV) lithography, DUV lithography (i.e., lithography in the deep ultraviolet spectral region), EUV lithography (i.e., lithography in the extreme ultraviolet spectral region), x-ray lithography, nanoimprint lithography, etc. These typically involve using masks (e.g., photomasks, exposure masks, reticles, stamps in the case of nanoimprint lithography, etc.), which comprise a pattern for imaging the desired structures on a wafer, for example.

Specifically EUV lithography is now of high industrial significance. For example, semiconductor chips produced by EUV lithography are essential for numerous applications in current technical infrastructure. However, numerous technical challenges, complex problems and constraints are associated with EUV lithography.

In the course of EUV lithography, for example, an EUV mask may be exposed to high physical and chemical stresses (for example, on mask exposure or mask cleaning). Accordingly, high demands are made on the stability of the mask materials of EUV masks. At the same time, the mask materials must also reliably ensure defined optical properties for EUV lithography.

Over the course of time, particular mask materials have become established for the imaging structures of an EUV mask (for example, tantalum compounds or chromium compounds for radiation-absorbing and/or phase-shifting structures). With progressive technical development in EUV lithography, however, the high demands on the mask materials may become even more severe. The focus is on optical properties in particular. But in order also to ensure mask materials that are still resistant in the case of improved optical properties, alternative mask materials and the production of EUV masks formed therefrom have recently been examined in the field of EUV lithography.

Since mask faults generally cannot be ruled out in the complex production of masks, (local) mask faults may form on the mask. The mask faults may include, for example, defects, missing material, excess material, malformed material, foreign particles and the like. In order to ensure the quality of EUV lithography, it is therefore typically necessary to repair the critical mask faults of an EUV mask.

However, existing methods of mask repair have been designed exclusively for industrially long-established mask materials.

It is therefore a general aspect of the present invention to improve this situation.

### SUMMARY

This general aspect is at least partly achieved by the various aspects of the present invention.

A first aspect of the invention relates to a method of processing a phase-shift mask for EUV lithography. The method comprises particle beam-induced depositing of a repair material using a precursor gas for repair of an imaging structure of the mask.

In one example, the imaging structure can be repaired in such a way that at least one critical dimension of the mask has a deviation from a predetermined critical dimension of at least below 15%, preferably below 10%, more preferably below 5%, most preferably below 3%. The admissible deviations mentioned from the predetermined critical dimension that are achieved via the repair may be regarded, for example, as a specification. According to the invention, for example, a phase-shift EUV mask can be repaired on-spec with the aid of particle beam-induced deposition of the repair material.

Phase-shift masks for EUV lithography are a relatively recent development in lithography. Phase-shift EUV masks must meet high optical demands, for example. Firstly, for example, the structures of the phase-shift EUV masks must absorb not only EUV radiation in EUV lithography. The structures of the phase-shift EUV masks must (additionally) enable a phase shift in the EUV radiation in a desired manner. The phase shift can achieve, for example, better lithography results (e.g., better contrast, NILS, etc.). However, it is also possible for there to be defective imaging structures on such phase-shift EUV masks. These can be repaired with the aid of the method according to the invention. The repair can be effected in such a way that at least one critical dimension of the mask fulfils the properties specified.

In one example, the at least one critical dimension may comprise a lateral extent of an optical and/or lithographic image of the repaired structure of the mask.

For example, the optical image may correspond to an optical image that would exist in the case of projection of the phase-shift mask by EUV lithography in a reference plane. The reference plane may correspond, for example, to a wafer plane in which a wafer would be positioned in EUV lithography.

In one example, the lateral extent of the optical and/or lithographic image may comprise a distance between a first edge in the image of the repaired structure and a second edge in the image of the repaired structure of the mask.

For example, the imaged repaired structure of the mask may be an (essentially) rectangular (e.g., linear) structure. In one example, the first edge and the second edge in the optical and/or lithographic image of the repaired structure that are used for the lateral extent may be juxtaposed such that the lateral extent corresponds essentially to a width of the image of the repaired structure.

For example, the lateral extent may correspond to a line width of the optical and/or lithographic image of the repaired structure. A critical dimension (CD) assigned to this line width may then be referred to, for example, as line CD.

For example, the lithographic image may correspond to a lithographic result produced in the case of projection of the phase-shift mask by EUV lithography.

For example, the critical dimension may exist in a resist pattern that has been produced by exposure of the mask with an EUV lithography system. What may take place here, for example, is exposure of a resist present on a wafer. The corresponding development of the resist may result in resist patterns (e.g., resist structures). The resist pattern may be regarded as a lithographic image of the mask.

Accordingly, a resist pattern corresponding to an image of the repaired structure may be used to determine the critical dimension (as described herein). The resist pattern may also be referred to in industry, for example, as a wafer print.

It should be mentioned here that all aspects described herein for the at least one critical dimension with regard to the optical image may correspondingly also be applicable to the at least one critical dimension in the lithographic image (for example in the resist pattern) (and vice versa). The term “image” may thus be applicable herein to an optical and/or lithographic image inter alia.

In one example, the optical image can be created by an EUV lithography system and/or with a mask examination system for EUV lithography. For example, the mask examination system for EUV lithography can simulate the conditions that would exist in actual EUV lithography. Such mask examination systems are known in industry.

In one example, the optical image may comprise an aerial image of the mask.

The optical image may comprise, for example, an aerial image of the phase-shift mask that would exist in EUV lithography. It is thus possible to ensure that the repair leads to an image in the course of EUV lithography in which the allowed deviations mentioned in the at least one critical dimension are fulfilled. The aerial image may be created, for example, with the mask examination system for EUV lithography.

It should be mentioned that the edges described herein can be used for determination of the critical dimension, for example from the aerial image of the phase-shift EUV mask. For example, the coordinates for determination of the at least one critical dimension can be determined from one or more aerial images of the mask.

In one example, the at least one critical dimension may comprise a lateral extent of an optical and/or lithographic image of an imaging structure adjacent to the structure repaired; and/or the at least one critical dimension may comprise a distance in an optical and/or lithographic image of the mask that comprises a distance between the image of the repaired structure and the image of an adjacent structure.

The critical dimension may thus also comprise a critical dimension associated with structures adjacent to the repaired structure.

The inventors have recognized that the repair process can influence not just a (single) lateral extent in the optical and/or lithographic image but also two or more kinds of lateral extents or critical dimensions. According to the invention, the repair process is implemented such that further kinds of critical dimensions can also be fulfilled, for example one or more of the critical dimensions elucidated herein.

In one example, the lateral extent of the optical and/or lithographic image may comprise a distance between a first edge in the image of a structure adjacent to the repaired structure and a second edge in the image of that structure adjacent to the repaired structure.

For example, the corresponding edges may be chosen such that one of the edges in the image of the adjacent structure has the shortest distance from the center of the image of the defective region of the repaired structure. It is thus possible to ensure that the region of the adjacent structure subjected to the repair also meets the conditions (described herein) for the critical dimension.

For example, the lateral extent may thus correspond to a line width of the optical and/or lithographic image of the structure adjacent to the repaired structure. According to the invention, the line width of this adjacent structure may thus satisfy the critical dimension defined. For example, this line width of the image of the adjacent structure may be determined at the site closest to the repair site.

In principle, a line width corresponding to a width of the optical and/or lithographic image of an imaging structure of the mask may also be referred to herein, for example, as line CD.

As mentioned, it is also possible in one example for a critical dimension to comprise a distance in an optical and/or lithographic image of the mask that comprises a distance between the image of the repaired structure and the image of an adjacent structure.

In this example, the critical dimension may thus comprise a distance between the repaired structure and the adjacent structure in a corresponding image.

A critical dimension which (as described herein) corresponds to the distance (in the images) between two adjacent imaging structures in an optical and/or lithographic image may also be referred to herein, for example, as interspace CD.

The method can thus be effected such that a line CD and/or an interspace CD in the region of the repaired structure do(es) not infringe the deviations (described herein) in the predetermined critical dimension.

In one example, the deviation from the predetermined critical dimension in two or more focal planes of the optical and/or lithographic image may be below 15%, preferably below 10%, more preferably below 5%, most preferably below 3%. For example, the deviation from the predetermined dimension in a first and second focal plane of the optical and/or lithographic image may be below 15%, preferably below 10%, more preferably below 5%, most preferably below 3%.

A focal plane (in the case of lithography) may, for example, be at +/−500 nm and/or +/−1000 nm (for example with respect to the reference planes described herein).

The critical dimension may, for example, also be defined depending on other EUV lithography parameters (e.g., dose, EUV mask type, EUV method, etc.). This may be taken into account, for example, by the optical and/or lithographic image of the repaired structure. For example, the optical and/or lithographic imaging can be effected, for example, in such a way that a defined set of EUV lithography parameters is fulfilled, such that the critical dimension can be assessed under various EUV conditions.

In one example, the deviation from the predetermined critical dimension at two or more exposure doses of the optical and/or lithographic imaging may be below 15%, preferably below 10%, more preferably below 5%, most preferably below 3%. For example, the deviation from the predetermined dimension at a first dose and at a second dose of the optical and/or lithographic imaging may be below 15%, preferably below 10%, more preferably below 5%, most preferably below 3%.

Moreover, an iterative approach in the method is also encompassed, in which the critical dimension is determined in the optical and/or lithographic imaging of the repaired structure and, on that basis, another repair operation (as described herein) takes place in order to further optimize the critical dimension.

In one example, a real part of a complex refractive index of an imaging structure of the mask may be between 0.88 and 0.99; and/or an imaginary part of the complex refractive index of an imaging structure of the mask may be between 0.01 and 0.08.

In one example, an imaging structure of the mask may comprise ruthenium.

The invention may address the problem of undertaking a repair of an EUV mask that may be a phase-shift mask and includes a ruthenium-containing material, which may provide novel chemical, physical and/or optical properties. Thus, it has not been customary to date (for example in the industrial sector of EUV lithography) to provide imaging structures with ruthenium-containing materials. However, there has recently been discussion as to whether structures of an EUV mask including a ruthenium-containing material should be created in order to do justice to current and future demands in EUV lithography.

By virtue of the ruthenium-containing material, for example, imaging structures formed therefrom (e.g., pattern elements) in the EUV mask may have improved optical properties and elevated chemical stability to the demands of EUV lithography. An imaging structure of the EUV mask may, for example, be a local structure of the EUV mask which is configured specifically for creation of a pattern in EUV lithography. The imaging structure may, for example, be specifically phase-shifting and/or radiation-absorbing in respect of the EUV lithography radiation (which may, for example, be in the region of 13.5 nm). The imaging structure may comprise, for example, a three-dimensionally configured geometry in terms of length, width and/or height, a topology step, an elevation and/or a depression in the EUV mask, or any topological deviation in relation to a planar plane of the EUV mask. For example, the ruthenium-containing material may account for at least one layer of the imaging structure of the EUV mask. For example, it is also possible for the whole imaging structure to be formed from the ruthenium-containing material.

In the light of mask development, the ruthenium-containing material of the imaging structure may have been designed specifically, for example, in order to explicitly prevent the removal of the imaging structure of the EUV mask under physical/chemical influences. The ruthenium-containing material may, for example, be designed so as to prevent removal/wear of structures formed therefrom even under sustained or regular chemical/physical stress. The ruthenium-containing material may, for example, be designed for the extreme conditions in EUV lithography under which the EUV mask is to be used. For example, the EUV mask may be exposed to a (damaging) plasma during a lithography method. For example, it may be necessary for a lithography method to expose the EUV mask to a hydrogen environment (for example for prevention of defects). In the case of lithographic exposure of the EUV mask, there may be release of a (parasitic) high-reactivity hydrogen plasma with free hydrogen radicals that can act on the material of the EUV mask. The plasma constitutes a high degree of chemical/physical stress on the EUV mask and can cause removal of material and damage to the material of the EUV mask (for example in a similar manner to plasma etching). However, the material-removing effect is undesirable in the EUV mask for lithography, since this can adversely affect the properties of the EUV mask and hence the quality of the EUV lithography. Therefore, the ruthenium-containing material of the imaging structure may be (explicitly) designed in order to assure high resistance of the material to the material-removing effect of a plasma (for example of the high-reactivity hydrogen plasma in particular). Moreover, the EUV mask may be subjected to numerous other mechanical/chemical influences in lithography, which can damage the EUV mask (for example in combination with the effect of plasma). For example, the other damaging influences may include severe temperature fluctuations, exposure radiation, and chemical reactions of the EUV mask with purge gases. The (novel) ruthenium-containing material may therefore typically be designed to fundamentally counteract the totality of the damaging material-removing effects in lithography, such that mechanical/chemical wear and removal of the ruthenium-containing material is made more difficult.

In the light of mask development, the ruthenium-containing material of the imaging structure may also have been specifically designed, for example, to specifically optimize optical properties of the EUV mask. For example, the ruthenium in the emitting structure of the phase-shift mask may cause a desired phase offset in EUV lithography.

The ruthenium-containing material may also be designed, for example, such that (unwanted) three-dimensional mask defects in an EUV mask are reduced. The two-/three-dimensional mask effects may include, for example, a telecentric fault, an attenuation of contrast and/or an offset in the optimal focus (for example a best focus shift) in EUV lithography. The ruthenium-containing material may also be designed, for example, to influence the scatter of EUV radiation at the edges of the imaging structure, such that phase errors caused by scatter in EUV lithography can be minimized.

The ruthenium-containing material of the imaging structure may thus have been specifically designed to enable novel chemical and novel optical properties of the EUV mask (for example the phase-shift EUV mask). The chemical/optical parameters of the ruthenium-containing material may also have been matched to the geometry of the imaging structures formed therefrom, in order to assure the desired interplay of the novel properties of the phase-shift EUV mask with EUV lithography. In one example, the entire imaging structure may have been formed from a single layer material, where the layer material comprises ruthenium. In a further example, the imaging structure may comprise two or more layers, where at least one layer material of the two or more layers comprises ruthenium.

The inventors have recognized that these mentioned imaging structures of ruthenium in phase-shift EUV masks can be repaired by a particle beam-induced deposition of a repair material in order to correct missing material, for example, in the imaging structure. The inventors have thus been able in particular to deposit material in a particle beam-induced manner such that the optical properties of the imaging structure have been improved, or brought into the target region, in a reliable and sustainable manner.

The basis of the inventive concept is accordingly that of repairing an imaging structure of a phase-shift EUV mask wherein the ruthenium-containing material fulfils a complex set of specific chemical and optical properties for EUV lithography via particle beam-induced deposition. In so doing, the inventors have hit on the unexpected finding that the imaging structure can be repaired on-spec with the aid of a particle beam-induced deposition using a provided precursor gas without otherwise significantly adversely affecting the complex optical properties of the corresponding phase-shift EUV mask. This was a surprising finding to the inventors since it was not foreseeable that, in a particle beam-induced deposition in the (immediate) environment of the defective imaging structure, the optical properties thereof can be improved via a repair, especially in such a way that they fulfil the specification for phase-shift EUV masks.

Finally, the ruthenium-containing material of the imaging structure fulfils a complex set of chemical and optical properties for EUV lithography that could have been irreversibly removed from equilibrium in many respects by direct particle beam-induced deposition.

For instance, it was not foreseeable whether, in the event of particle beam-induced deposition in the (immediate) environment of the imaging structure, the phase-shift EUV mask will possibly be destroyed even further, for example by the mechanical and/or chemical effect of the deposition. It was not foreseeable, for example, whether the deposition of the repair material will result in mechanical stresses that could lead, for example, to cracking and/or (partial) delamination of the imaging structure or the ruthenium-containing material thereof. Thus, it was also not apparent whether the deposition could irreversibly impair the optical properties of the imaging structure of the phase-shift EUV mask via a chemical and/or electrochemical effect. The deposited repair material may in principle be regarded as a chemical foreign body which is introduced into the environment of the ruthenium-containing material of the imaging structure. In this regard, it was not foreseeable whether this could result, for example, in occurrence of diffusion of elements from the deposited repair material into the ruthenium-containing material of the imaging structure, caused, for example, by corresponding chemical/electrochemical mechanisms. This could possibly have led to a significant effect on the complex optical properties in the region of the repaired structure that would have been a barrier to an actual repair.

The basis of the finding by the inventors is thus that particle beam-induced deposition can be effected in such a way that the optical properties of the phase-shift EUV mask can be reliably improved in the region of the defective imaging structure, such that the EUV mask can, for example, be brought on-spec.

The phase-shift EUV mask as described herein may comprise a lithography mask suitable for any kind of EUV lithography. The phase-shift EUV mask may comprise, for example, an attenuated phase-shift mask (attPSM) for EUV lithography. The phase-shift EUV mask may also comprise, for example, an alternating phase-shift mask (altPSM) for EUV lithography. It should be mentioned that phase-shift EUV masks or the phase-shifting imaging structures thereof also absorb the majority of the radiation. In the case of phase-shift masks, contrast does not result solely from the phase shift. The imaging structures may also cause (significant) absorption of radiation as well as the phase shift.

Particle beam-induced deposition of the repair material may take place, for example, within a defined working range in order to repair the imaging structure. In particle beam-induced deposition, the particle beam can be provided in the working region, where the working region may be exposed to the precursor gas in order to enable the deposition. The working region may comprise, for example, any local region of the EUV mask. The working region may include any areal dimension, shape and/or (three-dimensional) geometry. For example, the working region may comprise a defective region of the imaging structure to be repaired. A defective region may be regarded, for example, as a region wherein a layer material of the imaging structure is at least partly (or completely) absent. For example, the defective region may comprise a clear defect in the phase-shift EUV mask. A clear defect may be a faulty site on the EUV mask that should actually be phase-shifting and/or radiation-absorbing according to the design of the EUV mask. In one example, the method can be effected in such a way that a clear defect in the imaging structure of the phase-shift EUV mask has been (essentially) repaired. A clear defect may also be regarded as a faulty site on the object which is supposed to comprise a material of the imaging structure according to the design of the object, but no material is present at the site, or the material of the structure is absent. The clear defect can be minimized or remedied via deposition of the repair material in the region of the clear defect.

It is also conceivable that the working region, as well as the defective region of the imaging structure, also comprises a region adjoining the defective region. This edge region (around the actual defect region) may comprise an extent, for example, proceeding from an outer edge of the defective region of 400 nm to 5 nm, 300 nm to 5 nm, 300 nm to 5 nm, 50 nm to 5 nm. The edge region may also comprise an extent, for example, proceeding from an outer edge of the defective region of not more than 5%, not more than 10%, not more than 20%, not more than 50%, not more than 100% and/or not more than 200% of a diameter of the defective region. The diameter of the defective region may comprise, for example, a minimum or maximum diameter (or a minimum or maximum extent of the defective region). The dimensions of the edge region may also depend, for example, on the defective region.

The repair material may be deposited, for example, within the working region such that the repair material is not automatically deposited over the entire area of the working region. For example, the repair material can be deposited (locally) in a subregion of the working region. For example, the repair material may be deposited onto a subregion of the defective region mentioned herein and/or edge region of the imaging structure.

In one example, the repair material may be deposited at least over the whole area of the defective region of the imaging structure. For example, there may be at least partial deposition of repair material on the edge region. However, the method can also be controlled in such a way that essentially no deposition of repair material on the edge region described herein takes place. It is also conceivable that the repair material is deposited fully over the entire working region, for example in the defective region and the edge region described herein.

In addition, the precursor gas may be provided in a controlled manner in a subregion of the working region (for example via a locally positionable gas conduit with a gas nozzle). It is likewise possible for the particle beam to be provided in that it is directed onto a subregion of the working region such that the particles of the particle beam are incident on the subregion. In addition, the method may comprise (temporally) specific local control and/or focusing of the particle beam in the subregion or within the working region (in order, for example, to control a reaction in the particle beam-induced deposition locally, and also temporally).

In a further example, the at least one layer material of the imaging structure comprising ruthenium (as described herein) may be formed predominantly from ruthenium. For example, the ruthenium content of the corresponding layer material of the imaging structure may comprise at least 50 atom percent (at %), at least 70 atom percent, at least 80 atom percent, or at least 90 atom percent.

The unit “atom percent,” as described herein, may relate to a molar proportion of the corresponding material, where atom percent indicates, for example, the relative number of particles (e.g., ruthenium atoms) in relation to the total number of particles of the substance (for example total number of atoms of the layer material). The atomic percentage may be detected, for example, via secondary ion mass spectrometry, SIMS, and/or Auger electron spectroscopy and/or x-ray photoelectron spectroscopy, XPS (and also, for example, via photoelectron spectroscopy, PES).

The method of the first aspect as described herein is fundamentally also conceivable with a different ruthenium content of the at least one ruthenium-comprising layer material. For example, the corresponding ruthenium content may be lower than 50 atom percent or lower than 10 atom percent, or else lower than 1 atom percent. The ruthenium content of the layer material of the imaging structure may also comprise, for example, at least 10 atom percent, at least 25 atom percent or at least 35 atom percent.

It has been found that imaging structures comprising one or more layers of the ruthenium-comprising layer materials as mentioned herein can be processed by the method of the first aspect.

It should be mentioned that the imaging structure or the ruthenium-comprising layer material thereof, as well as ruthenium, may also comprise further elements.

In one example, the imaging structure may further comprise tantalum. For example, the imaging structure may comprise a ruthenium-tantalum compound (e.g., RuTa). In one example, the imaging structure may have a single layer material formed essentially from a ruthenium-tantalum compound.

In one example, the imaging structure may further comprise at least one of the following elements: rhenium, tellurium, tungsten, boron, nitrogen, oxygen. For example, the imaging structure may comprise a ruthenium-rhenium compound (e.g., RuRe). In addition, it is also conceivable that the imaging structure may comprise a ruthenium-tellurium compound (e.g., RuTe). For example, the imaging structure may also comprise a ruthenium-tungsten compound (e.g., RuW).

In one example, the imaging structure may further comprise at least one of the following elements: rhodium, palladium, chromium, rhenium, osmium, iridium, gold, platinum, silver, technetium, molybdenum, tungsten, cadmium, indium.

In one example, the precursor gas may comprise ruthenium.

In one example, the precursor gas may comprise a metal carbonyl comprising ruthenium.

In one example, the precursor gas may comprise at least one of the following:
triruthenium dodecacarbonyl, bis(ethylcyclopentadienyl)ruthenium(II), ruthenocene, ruthenium pentacarbonyl, allylruthenium(II) tricarbonyl bromide, allylruthenium(II) tricarbonyl chloride, ruthenium tetracarbonyl iodide, ruthenium(III) nitrosylchloride monohydrate, dichlorotricarbonylruthenium(II) dimer, hexaammineruthenium(III) chloride, benzeneruthenium(II) chloride, dimer, carbonylchlorohydridotris(triphenylphosphine)ruthenium(II), tetrakis(dimethylsulfoxide)dichlororuthenium(II), ruthenium(III) nitrosylnitrate, ruthenium(III) nitrosylsulfate, ruthenium(III) nitrosylacetate, ruthenium (VIII) oxide, tris(2,2′-bipyridyl)ruthenium(II) chloride, chloropentaammineruthenium(III) chloride, ruthenium(III) acetylacetonate, tetraamminechlorohydroxyruthenium(III) chloride, ruthenium(III) chloride, ruthenium(III) bromide, dichlorotris(triphenylphosphine)ruthenium(II), dihydrotetrakis(triphenylphosphine)ruthenium(II), (hexamethylbenzene)ruthenium(II) dichloride, dimer, chloro(cyclopentadienyl)bis(triphenylphosphine)ruthenium(II), ruthenium (IV) sulfide, chloro(4,4′-dicarboxy-2,2′-bipyridine) (p-cymene)ruthenium(II) chloride.

In the examples in which the precursor gas comprises ruthenium, the ruthenium may be deposited in the repair material in the particle beam-induced deposition. For the process of the first aspect, this has been found to be advantageous since, in these examples too, the optical quality of the EUV mask can be assured via the corresponding repair. For example, it is thus possible to enable the critical dimensions of the EUV mask as described herein.

In one example, the repair material may comprise ruthenium.

The ruthenium content of the repair material may correspond, for example, to the ruthenium content described herein in the at least one layer material of the imaging structure.

In one example, the repair material may further comprise at least one further element of the imaging structure. The at least one further element may be encompassed as an essential element in the imaging structure (for example, at least 1 atom percent). For example, this further element may not be regarded as a trace element in the imaging structure. The at least one further element may thus influence the properties of the ruthenium-comprising imaging structure (for example, without the further element, the imaging structure would have different chemical/physical and optical properties). In one example, the repair material may comprise at least two further elements of the imaging structure.

In one example, the repair material may further comprise tantalum. For example, the repair material may comprise a ruthenium-tantalum compound (e.g., RuTa).

In one example, the repair material may further comprise at least one of the following elements: rhenium, tellurium, tungsten, boron, nitrogen, oxygen. For example, the repair material may comprise a ruthenium-rhenium compound (e.g., RuRe). In addition, it is also conceivable that the repair material may comprise a ruthenium-tellurium compound (e.g., RuTe). For example, the repair material may also comprise a ruthenium-tungsten compound (e.g., RuW).

In one example, the repair material may essentially correspond to the material composition of the imaging structure. For example, the repair material may correspond essentially to the stoichiometry of the imaging structure or to the stoichiometry of the at least one ruthenium-comprising layer material.

In one example, the particle beam-induced depositing of the repair material may also be effected with use of an additive gas.

The additive gas may comprise, for example, an oxygen-containing component, a halide and/or a reducing component.

The oxygen-containing component may include, for example, an oxygen-containing molecule.

For example, the oxygen-containing component may comprise at least one of the following: oxygen (O₂), water (H₂O), heavy water (D₂O), semi-heavy water (HDO), ozone (O₃), hydrogen peroxide (H₂O₂), dinitrogen monoxide (N₂O), nitrogen monoxide (NO), nitrogen dioxide (NO₂), nitric acid (HNO₃).

The halide may include, for example, at least one of the following: Cl₂, HCl, XeF₂, HF, I₂, HI, Br₂, HBr, NOCl, NOF, ClNO₂, FNO₂, PCl₃, PCl₅, PF₃, PF₅.

The reducing component here may comprise a molecule having a hydrogen atom. For example, the reducing component may comprise at least one of the following: H₂, NH₃, (NH₂)₂, CH₄.

The additive gas may additionally also comprise, for example, one of the following: CO, NF₃, F₂, Cl₂, PH₃, SH₂, SO₂, SFₓ, SC₁ₓ.

The additive gas can further influence the particle beam-induced deposition of the repair material and can, for example, more specifically adapt process parameters/results (e.g., deposition rate, sidewall angle, surface roughness, etc.). By use of the additive gas, it is additionally also possible to adjust the optical properties of the repair material or else the composition of the repair material. For example, it is possible via the additive gas to influence a real part of a complex refractive index and/or an imaginary part of a complex refractive index of the repair material. In addition, the additive gas can also make it possible to reduce unwanted constituents in the deposited repair material (e.g., carbon). In this case, the additive gas can, for example, convert the unwanted constituents to a desorbable, volatile form.

In addition, it is also conceivable that, via the choice of additive gas or an adjustment in the process parameters of the additive gas (e.g., gas flow, gas flow rate, gas concentration), the optical properties of the repair material are influenced such that these correspond to a layer material of an imaging structure of a specific EUV mask type. It is thus possible for the repair process (described herein) to take place depending on the mask to be repaired or depending on an EUV mask type. It is thus possible via the method described herein, for example, to produce various radiation-absorbing and/or phase-shifting repair materials that are specific for particular masks.

In one example, a deviation of a real part of a complex refractive index of the repair material from a real part of a complex refractive index of an imaging structure of the mask may be less than 7%, preferably less than 5%, more preferably less than 3%, most preferably less than 2%.

In one example, a complex refractive index of the repair material may have an imaginary part β such that a deviation of the value 1−β from the value 1−βᵣ is less than 5%, preferably less than 4%, more preferably less than 3%, most preferably less than 2%, where βᵣ is an imaginary part of a complex refractive index of an imaging structure of the mask.

In one example, a complex refractive index of the repair material may have an imaginary part β such that a deviation of the value 1−β from the value 1−βᵣ is less than 1%, or less than 0.5%.

In one example, a real part of a complex refractive index of the repair material may comprise a value within a range between 0.88 and 0.99, preferably between 0.88 and 0.96, more preferably between 0.88 and 0.92.

In one example, an imaginary part of a complex refractive index of the repair material may comprise a value within a range between 0.005 and 0.08, preferably between 0.01 and 0.06, more preferably between 0.01 and 0.04.

In one example, the precursor gas may comprise rhodium.

In one example, the imaging structure may comprise rhodium. The imaging structure of the phase-shift EUV mask need not necessarily comprise ruthenium. According to the invention, it is thus also possible to repair rhodium-containing imaging structures that do not include ruthenium.

In one example, the imaging structure of the phase-shift EUV mask may include rhodium and ruthenium. According to the invention, it is thus also possible to repair rhodium- and ruthenium-containing imaging structures.

In one example, the precursor gas may comprise a metal carbonyl comprising rhodium.

In one example, the precursor gas may comprise at least one of the following: tetrarhodium dodecacarbonyl, rhodium carbonyl chloride, di-eta-chloro-tetrakis(phosphorus trifluoride)dirhodium, hexarhodium hexadecacarbonyl, rhodium octanoate dimer, rhodium(III) trifluoroacetylacetonate, rhodium(III) nitrate anhydrous, dirhodium(II) tetrakis(caprolactam), acetylacetonatobis(ethylene)rhodium(I), chlorobis(ethylene)rhodium(I) dimer, rhodium(II) acetate dimer, rhodium(III) chloride trihydrate, hydridotetrakis(triphenylphosphine)rhodium(I), dicarbonyl(2,4-pentanedionato)rhodium(I), rhodium(III) oxide (anhydrous), rhodium(III) acetate, rhodium(II) trifluoroacetate dimer, tetrakis(1,5-cyclooctadiene)tetra-μ-hydridotetrarhodium, pentaamminechlororhodium(III) dichloride.

In one example, the repair material may comprise rhodium.

In one example, the precursor gas may comprise chromium. It has been found that, for the repair of an imaging structure of a phase-shift EUV mask, a chromium-based precursor gas is reliably suitable.

In one example, the precursor gas may comprise a metal carbonyl comprising chromium.

In another example, the chromium may be encompassed in a further constituent of the precursor gas (for example, a further gas of the precursor gas), but not in the metal carbonyl. In addition, it is also conceivable that the chromium is encompassed in the further constituent of the precursor gas and the metal carbonyl.

In one example, the metal carbonyl may comprise a chromium carbonyl. For example, the chromium carbonyl may comprise chromium hexacarbonyl.

In one example, the repair material may comprise chromium. It has been found that chromium-based repair material is reliably suitable as repair material for phase-shift EUV masks. Damaging mechanical, chemical and/or optical effects were not able to be attributed to chromium-based repair material. Instead, chromium-based repair material can be used in such a way that the critical dimensions described herein can be fulfilled after a repair. In addition, chromium-based repair material has been found to be a chemically resistant repair material for phase-shift EUV masks.

In one example, the repair material may further comprise oxygen. For example, the precursor gas may comprise an (oxygen-containing) oxidizing agent, such that oxygen is also added to the repair material. This can additionally increase the chemical resistance of the repair material. For example, this can reduce an unwanted fraction of carbon in the repair material.

In one example, the repair material may comprise a chromium-oxygen compound, CrₓO_{y}. For example, CrₓO_{y} may comprise at least one of the following compounds: Cr₂O₃, CrO, CrO₂, CrO₃, Cr₃O₈, Cr₂O₅, CrO₂.

For example, the repair material may comprise any kind of chromium oxide.

In one example, the real part of a complex refractive index of the repair material may comprise a value within a range between 0.92 and 0.99, between 0.93 and 0.98, between 0.934 and 0.974, or between 0.94 and 0.965.

In one example, the imaginary part of a complex refractive index of the repair material may comprise a value within a range between 0.01 and 0.07, between 0.015 and 0.06, between 0.025 and 0.05, or between 0.03 and 0.045.

In one example, the method (in the first aspect) of processing a phase-shift mask for EUV lithography may comprise:
determining a repair site on the mask where an imaging structure of the mask is considered to be faulty;
determining at least one reference site on the mask where an imaging structure of the mask is considered not to be faulty;
particle beam-induced depositing of a repair material (RM) at the repair site using a precursor gas;
wherein the particle beam-induced depositing is effected such that a height (d2) at the repair site is greater than a height (d1) at the at least one reference site.

The repair material here may be deposited to repair the repair site and hence to repair the corresponding imaging structure considered to be faulty.

The repair site can be determined, for example, in an automated or semiautomated manner or manually. For instance, corresponding procedures for determination of defects in mask repair are known.

It is likewise possible to determine the reference site, for example, in an automated or semiautomated manner or manually. As mentioned, the reference site may be considered to be a non-faulty site in an imaging structure. For example, it is possible to look for a non-faulty site in an imaging structure on the mask, which is used as reference site for the particle beam-induced deposition. The reference site may be regarded, for example, as a defect-free (“healthy”) site on the mask where no significant deviations of the mask are expected. The mask may thus cause desired properties at the reference site in terms of optical and/or lithographic imaging (without significant deviations). Corresponding reference sites can be determined, for example, via imaging methods (for example, via a particle beam image). There are thus typically isolated defects of imaging structures on the mask, which can be delimited from defect-free imaging structures or defect-free sites of imaging structures thereof.

The mask may thus have properties at the reference site that should actually be possessed by the repair site if the repair site were not faulty. For example, the reference site may have a height that should also (essentially) exist at the repair site if it were not faulty. With the present approach, the reference site is therefore used as reference for the repair of the repair site. In addition, it is also possible to use more than one reference site for the approach described herein (for example, two, three or more reference sites).

It has been found to be a suitable procedure that, in the repair of phase-shift EUV masks, the height at the repair site and the height at the reference site should not necessarily be essentially equal (as known for instance from the repair of other kinds of lithography masks).

Instead, it has been found that, for a repair of phase-shift EUV masks, deposition at the repair site should be such that the height at the repair site is greater after the repair than the height at the reference site. After the repair, there is thus an excess of height at the repair site relative to the reference site. The height of the imaging structure at the repair site in this example after the repair is thus greater than the height of the imaging structure at the (defect-free) reference site. This can be comprehended, for example, via a particle beam image or an atomic force microscope image (e.g., an AFM).

The height of an imaging structure may be based on a reference layer of the phase-shift EUV mask. The reference layer may correspond, for example, to a protective layer of the EUV mask. The normal to the reference layer may be used for the determination of the height at the reference site and the determination of the height at the repair site. Thus, the uppermost (i.e., highest) position of the repair material on the normal proceeding from the reference layer may be regarded as the height at the repair site. For example, the imaging structure may directly adjoin the reference layer. In that case, the distance between the uppermost point of the repair material at right angles to the surface of the reference layer would correspond to the height described herein at the repair site. Analogously, the uppermost (i.e., highest) position of the imaging structure at the reference site may be used for determination of the height thereof. The uppermost position of the imaging structure at the reference site may also result, for example, from an upper plateau of the imaging structure.

It has been found to be advantageous to implement the type of height excess mentioned at the repair site by comparison with an actually defect-free reference site. It is thus possible for the height excess mentioned at the repair site to make a major contribution to repair of the mask at the repair site such that deviations in the optical and/or lithographic image are minimized. This approach can thus make it possible for at least one critical dimension of the mask to have a deviation from a predetermined critical dimension of at least below 15%, preferably below 10%, more preferably below 5%, most preferably below 3% (as described herein).

In one example, the reference site can be determined in such a way that the height at the reference site is assumed to be essentially the same as at the repair site if the repair site were not faulty, preferably via consideration of corresponding sites on the mask. The reference site can thus be determined based on an assumption. This can be effected manually, for example. For example, a user can use a particle beam image to look for defect-free sites in the region of the repair site. It is possible here to make use, for example, of corresponding sites. For example, imaging structures may occur repeatedly on the mask in terms of their structure. These repeating structures should typically have (essentially) the same properties, in particular the same height. Accordingly, in the case of determination of the repair site, it is possible to determine a reference site corresponding to the repair site (for example, the reference site may be chosen in an imaging structure similar to the imaging structure of the repair site). It is likewise possible for the corresponding area of the reference site to be on the same imaging structure (as described herein). The reference site can also be determined in an automated manner, for example with the aid of a corresponding search algorithm that considers and evaluates, for example, a particle beam image (for example, an electron beam image) of the mask.

In one example, the reference site may be determined in such a way that the reference site and the repair site should have the same height in relation to a specification of the mask. The specification may, for example, be a height specification of the mask. For example, it is possible to predetermine via the specification what heights should be present at what point on the mask. For example, there may be a corresponding database in which this is recorded. It is likewise conceivable that it is predetermined by the specification that particular imaging structures should have particular height properties. This information can be used for the determination of the reference site.

By use of the specification, the reference site can for example be determined in an automated or semiautomated manner or manually.

In one example, the repair site and the reference site may adjoin one another. The reference site can thus be determined in such a way that it is directly alongside the (at least one) repair site. After the repair, it would thus be clear that the height at the repair site is greater in relation to an adjoining plateau of the reference site of the imaging structure. The repair material may thus project above defect-free uppermost positions.

In one example, the repair site and the reference site may be spatially separated from one another. The reference site can thus be determined in such a way that the reference site does not directly adjoin the repair site. It is thus possible to choose a particular distance between reference site and repair site.

In one example, it may be the case in the method that, in relation to a construction of the mask, the repair site and the reference site would lie on the same imaging structure if the repair site were not faulty. For example, an imaging structure may be interrupted at the repair site, such that the imaging structure at the repair site is at first considered to be faulty before the repair. By the repair, this interruption can be filled by the repair material, such that a coherent structure is formed again after the repair. The reference site in this regard may thus be a site in the (theoretical) coherent structure that should actually be present if the structure were not faulty.

In one example, it may be the case in the method that, in relation to a construction of the mask, the repair site lies on a first imaging structure, and the reference site lies on a second imaging structure; wherein the first imaging structure and the second imaging structure are different, and these are preferably imaging structures adjacent to one another. The reference site thus need not necessarily lie on the same structure as the repair site.

In one example, the height at the repair site may comprise a height of not more than 300%, not more than 180%, not more than 150%, not more than 120% or not more than 110% of the height at the reference site.

In one example, a difference of the height at the repair site from the height at the reference site may correspond to a value within a range from 0 nm to 150 nm, 0 nm to 30 nm, 0 nm to 20 nm, 0 nm to 10 nm, or 0 nm to 5 nm.

In one example, the height at the reference site may correspond to a value within a range from 10 nm to 100 nm, 10 nm to 80 nm or 10 nm to 70 nm.

In one example, the method may further comprise the determining (e.g., measuring) of the height at the reference site. It is thus possible here to quantitatively determine the height at the reference site (for example, via standard methods from the semiconductor industry).

In addition, the method may also comprise the determining of the height at the repair site before and/or after the particle beam-induced depositing.

In one example, the particle beam-induced depositing can be effected in such a way that a height of the repair material is greater than a target height of the structure, where the target height of the structure corresponds to a height of the structure at a non-faulty site.

For example, the target height of the structure may correspond to a predetermined target height of the imaging structure to be repaired, where the predetermined target height corresponds to a height of the structure to be repaired at a non-faulty site.

The predetermined target height may correspond, for example, to a predetermined value where it is known that this corresponds to a standard height of the imaging structures of the masks. For example, it may be known in principle that the imaging structures of the mask have a height of hx, such that the height at the repair site must have a height greater than hx. For example, it is not necessary to actively look for a reference site since this predetermined target height is simply employed, with deposition of the repair material such that it is above this predetermined target height.

The non-faulty site of the (predetermined) target height may in one example also be regarded as a reference site, in which case this need not explicitly be a position on the mask, although it is a fundamental assumption that the target height is present at the reference site.

The height of the repair material or the (predetermined) target height may (likewise) be based on a reference layer of the phase-shift EUV mask. The reference layer may correspond, for example, to a protective layer of the EUV mask. The normal to the reference layer may be used, for example, for the determination of the height of the repair material or of the target height of the structure. Thus, the uppermost (i.e., highest) position of the repair material on the normal proceeding from the reference layer may be regarded as the height of the repair material. For example, the imaging structure may directly adjoin the reference layer. In that case, the distance between the uppermost point of the repair material at right angles to the surface of the reference layer would correspond to the height described herein of the repair material.

The height of the imaging structure may also be formed correspondingly. Thus, the uppermost (i.e., highest) position of the imaging structure on the normal proceeding from the reference layer may be regarded as the height of the imaging structure. As mentioned, the imaging structure may, for example, directly adjoin the reference layer, such that, in this case, the total height of the imaging structure proceeding from the reference layer would correspond to the height of the imaging structure.

The (predetermined) target height of the structure may be defined, for example, from the mask manufacture. For example, there may be specification for the phase-shift EUV mask of the region in which the heights of the imaging structures are present.

As mentioned, it has been found that, for assurance of repair quality, the repair material may have excess dimensions in relation to the target height of the structure. Such (excessively high) deposition may make it possible, for example, for the repair of the phase-shift EUV mask to fulfil the critical dimensions (described herein). The repair material used (for excessive height) may, for example, be a repair material as described herein.

As mentioned, the (predetermined) target height may correspond to a height of the structure at a non-faulty site. The particle beam-induced deposition can thus be effected in such a way that the repair material is excessively high compared to a non-faulty site of the imaging structure. For example, the height of the imaging structure can be determined quantitatively at the non-faulty site (for example via an atomic force microscope, a scanning electron microscope, an optical test method, etc.). The value determined for the height of the imaging structure can then be used as target height of the structure. The non-faulty site may, for example, lie in the region of, for example directly adjoin, the site to be repaired.

In one example, a height of the repair material may comprise a height of not more than 300%, not more than 180%, (preferably) not more than 150%, (more preferably) not more than 120%, or (most preferably) not more than 110% of a (predetermined) target height of the structure.

There are conceivable scenarios, for example, in which minimization of the excess height of the repair material may be advantageous. In the case of irradiation of the phase-shift mask with EUV light, which is typically effected at an oblique angle of incidence, shadowing effects, for example, may be caused by structures of the mask. The shadowing effects can impair the optical and/or lithographic imaging of the mask. By means of minimization of the excess height of the repair material, it is possible to avoid or at least reduce such shadowing effects that are caused by the repair material. At the same time, it is possible to ensure, for example, that the at least one critical dimension is fulfilled by virtue of the repair material.

In one example, the height of the repair material may correspond to at least 110%, at least 130%, at least 150%, at least 200% or at least 300% of the (predetermined) target height of the structure.

In one example, a difference of a height of the repair material from a (predetermined) target height of the structure may correspond to a value within a range from 0 nm to 150 nm, 0 nm to 30 nm, 0 nm to 20 nm, 0 nm to 10 nm, or 0 nm to 5 nm.

In one example, a difference of a height of the repair material from a (predetermined) target height of the structure may correspond to a value in the range from 0.5 nm to 150 nm, 0.5 nm to 80 nm, 0.5 nm to 50 nm, 0.5 nm to 30 nm, or 0.5 nm to 20 nm.

In one example, the (predetermined) target height of the structure may correspond to a value within a range from 10 nm to 100 nm, 10 nm to 80 nm or 10 nm to 70 nm.

In one example, the excess height of the repair material relative to a non-faulty site on the imaging structure may correspond to a value in the range from 2 nm to 100 nm, 5 nm to 80 nm, 10 nm to 70 nm or 20 nm to 60 nm.

In one example, the height of the repair material compared to the (predetermined) target height is greater by at least 10 nm, by at least 20 nm, by at least 40 nm, by at least 80 nm, by at least 110 nm.

In one example, the (predetermined) target height of the structure may correspond to a value in the range from 20 nm to 90 nm, 30 nm to 80 nm or 40 nm to 60 nm.

In one example, the particle beam-induced depositing may be effected in such a way that a lateral extent of the repair material is different from a lateral target extent of the structure, wherein the lateral target extent of the structure corresponds to a lateral extent of the structure at a non-faulty site of the structure.

It has been found that, for the assurance of optical quality of the repaired phase-shift EUV mask, the lateral extent of the repair material may also be varied. For example, the specification of the EUV mask may include the region in which the predetermined lateral target extent of the structure may lie. For example, the predetermined lateral target extent of the structure may correspond to a width of the imaging structure on the phase-shift EUV mask. In the repair, the repair material can be deposited in such a way that the lateral extent thereof is, for example, lower or higher than, for example, the lateral extent of the structure. For example, the repair material may have a lower line width or a higher line width than the line width of the structure on the mask.

For example, the lateral target extent of the imaging structure can be determined quantitatively at the non-faulty site (for example, via an atomic force microscope, a scanning electron microscope, an optical test method, etc.). The value determined for the lateral extent of the imaging structure can then be used as the predetermined lateral target extent of the structure. The non-faulty site may, for example, lie in the region of, for example directly adjoin, the site to be repaired.

It is possible via the geometry effect of the adjustment of the lateral extent of the repair material to implement the critical dimensions described herein in the repair.

For example, for an optimization of the critical dimension, the excess height of the repair material can also be combined with the adjustment of the lateral extent of the repair material. In addition, it is also conceivable that the critical dimensions are assured by an adjustment of the lateral extent of the repair material, and the height of the repair material corresponds essentially to the target height of the structure. In addition, optimization exclusively via the height of the repair material is also conceivable, in which case the lateral extent of the repair material corresponds essentially to the target extent of the structure. It should be mentioned that the geometric adjustments described herein (target height or target extent) can be combined with the further options of the method in the first aspect (for example including in combination with different precursor gases, additive gases, as described herein).

In one example, the lateral extent of the repair material may comprise a value that varies from the lateral target extent of the structure by not more than 80%, not more than 50%, not more than 30%, or not more than 10%.

In one example, the lateral target extent of the structure may be lower than 300 nm, preferably lower than 200 nm, more preferably lower than 100 nm, most preferably lower than 80 nm.

In one example, the lateral extent of the repair material may be lower than 400 nm, lower than 300 nm, lower than 200 nm, or lower than 100 nm.

In one example, the difference between the lateral extent of the repair material and the lateral target extent of the structure (for example at a non-faulty site on the structure) may be lower than 50%, lower than 30%, lower than 20%, lower than 10%, lower than 5%, of the lateral target extent of the structure.

In one example, the lateral extent of the repair material may comprise at least 50%, preferably at least 70%, more preferably at least 80%, most preferably at least 90%, of the lateral target extent of the structure.

In one example, the lateral extent of the repair material may be lower than 200%, preferably lower than 150%, more preferably lower than 130%, most preferably lower than 120%, of the lateral target extent of the structure. But it may also comprise at least 105%, 110%, 120% or at least 130% of the lateral target extent of the structure.

In one example, deviations in the geometry of the repair material can interact synergistically. For example, it may be helpful to make the lateral extent of the repair material somewhat broader than the lateral target extent of the structure. At the same time, it is possible, for example, to choose a greater height of the repair material than the target height of the structure. These two deviations can interact in some examples such that the imaging properties of the repaired structure correspond closely to those of the target structure.

In one example, in the method in the first aspect, the particle beam (in the particle beam-induced deposition) is based at least partly on an acceleration voltage of less than 3 kV, less than 1 kV, less than 0.8 kV, less than 0.6 kV, or less than 0.4 kV. The method in the first aspect (as described herein) can advantageously be effected in these ranges of acceleration voltage. For example, in this parameter space, the repair material can advantageously be deposited with the particle beam. In one example, the particle beam is also based on an acceleration voltage of at least 0.1 kV, at least 0.15 kV, at least 0.2 kV, or at least 0.3 kV.

In addition, it is also conceivable that the particle beam is based on an acceleration voltage of less than 30 kV, preferably less than 20 kV. In one example, an acceleration voltage between 3 kV and 30 kV may be employed for imaging purposes within the method (in the case of imaging before or after the deposition and/or imaging during the deposition).

In one example, the particle beam (in the case of particle beam-induced deposition) comprises a current between 1 pA and 100 pA, preferably between 5 pA and 80 pA, most preferably between 10 pA and 60 pA.

The method described herein may, for example, be recorded in written form. This can be achieved, for example, by use of a digital file, by analogue means (for example, in paper form), in a user handbook, in a formula (recorded, for example, in a device and/or a computer at a semiconductor factory). It is also conceivable that a written protocol is compiled on execution of the method described herein. The protocol may enable, for example, proof of the execution of the method and details thereof (for example, the formula) at a later juncture (for example, in the course of a fault assessment, a material review board, an audit, etc.). The protocol may comprise, for example, a protocol file (i.e., log file) which can be recorded, for example, in a device and/or computer.

A second aspect relates to a phase-shift mask for EUV lithography that has an imaging structure, wherein the imaging structure has been repaired via particle beam-induced deposition of a repair material using a precursor gas.

In one example, an imaging structure of the mask may have been repaired at a repair site via particle beam-induced deposition of a repair material (RM) using a precursor gas; wherein a height at the repair site is greater than a height at at least one reference site on the mask at which an imaging structure of the mask is considered not to be faulty, without particle beam-induced deposition of the repair material at the reference site.

In one example of the phase-shift mask in the second aspect, as a result of the repairing of the imaging structure, a critical dimension of the mask may have a deviation from a predetermined critical dimension of at least below 15%, preferably below 10%, more preferably below 5%, most preferably below 3%.

It should be noted that the features described herein with regard to the method in the first aspect may also be correspondingly applicable to the phase-shift mask for EUV lithography in the second aspect.

For instance, in one example, an imaging structure of the mask may have a layer material comprising ruthenium.

For instance, in one example, an imaging structure of the mask may have a layer material comprising rhodium.

The properties and/or features for the critical dimension and/or predetermined critical dimension that are described herein for the method in the first aspect are correspondingly also applicable to the mask in the second aspect. For example, the critical dimension may exist in the case of optical and/or lithographic imaging of the mask in EUV lithography, which can be determined, for example, via a mask inspection system.

In one example of the second aspect, the at least one critical dimension may comprise a lateral extent of an optical and/or lithographic image of the repaired structure of the mask.

In one example, the mask (in the second aspect) may have been processed (or repaired) by a method in the first aspect.

It is possible here, for example, via an optical analysis of the EUV mask, to detect whether the EUV mask has been processed by a method in the first aspect. For example, for the EUV mask, an optical analysis may initially have been conducted, or may be undertaken (for example, in the course of defect qualification of the EUV mask, for example, after production of the EUV mask and/or in the case of introduction of the EUV mask into a semiconductor works). The optical analysis may be based, for example, on an optical or particle-based microscope (for example, on a mask inspection system, a mask metrology device, a mask microscope) and comprise, for example, an imaging operation. In the processing of the EUV mask in one example of the first aspect, after the initial analysis, the repair material may have been deposited as described herein. The deposition of the repair material can be detected via a repeated visual analysis (for example, in the course of a repair check or another defect qualification). The detection may be effected, for example, via a comparison of the initial visual analysis with the repeated visual analysis (for example, via a comparison of the corresponding images). In addition, the detection in the method may also be based on a material analysis of the EUV mask (for example, Auger spectroscopy, x-ray spectroscopy, etc.), which, for example, is executed in a supplementary manner with the initial or repeated visual analysis. For example, a material analysis of the repair material can be effected, such that the properties thereof (as described herein) can be examined.

A third aspect relates to a computer program comprising instructions which, when executed by a computer system, cause the computer system (and/or a device, for example, a device in the fourth aspect described herein) to execute a method in the first aspect.

A further aspect relates to a computer program comprising necessary component steps of the method as instructions (for example, control signals for implementation of the particle beam-induced deposition, control of the mask holder, control of the gas flow, etc.).

A fourth aspect relates to a device for processing of a phase-shift mask for EUV lithography, comprising: means of particle beam-induced deposition of a repair material using a precursor gas for repair of an imaging structure of the mask; a computer system comprising the computer program in the third aspect. The computer system may comprise, for example, one or more storage media that may each comprise one or more instructions from the computer program in the third aspect.

Alternatively, it is also possible for the computer program to be stored elsewhere (e.g., in a cloud) and for the device to merely have means for receiving instructions that arise from executing the program elsewhere. Either way, this may allow the method to run in automated or autonomous fashion within the device. Consequently, it is also possible to minimize the intervention, for example by an operator, and so it is possible to minimize both the costs and the complexity when processing masks.

The features (and also examples) of the method in the first aspect that are specified herein may also be applied or applicable correspondingly to the device mentioned (and also the computer program mentioned). The features (and also examples) of the device (and also the computer program) that are specified herein may likewise be applied or be applicable correspondingly to the method in the first aspect described herein. Moreover, the features of the aspects described herein are fundamentally combinable with one another.

A fifth aspect relates to a lithography method for lithographic processing of a semiconductor-based wafer, comprising: lithographic transfer of a pattern on a mask in the second aspect to the wafer, wherein the mask has been processed by a method in the first aspect. The pattern may comprise the imaging structure mentioned herein. The lithographic transfer may comprise an EUV lithography method for which the EUV mask is designed. For example, the method in the fifth aspect may comprise providing a beam source of electromagnetic radiation (e.g., EUV radiation). This may additionally comprise a provision of a developable resist layer on the wafer. The lithographic transfer may also be based at least in part on the radiation source and the provision of the developable resist layer. It is possible here, for example, by use of the radiation from the radiation source, to image the pattern onto the resist layer (in a transformed form).

Even though the aspects of the invention are described here primarily in relation to masks for EUV lithography, they may nevertheless also find use for other masks or else for repair of other (for example semiconductor-based) elements, such as wafers.

### DESCRIPTION OF DRAWINGS

The detailed description that follows describes technical background information and working examples of the invention with reference to the figures, which show the following:

FIG. 1 illustrates, in a top view, scanning electron micrographs of an EUV mask in the region of a defective imaging structure before and after an illustrative repair operation.

FIG. 2 illustrates, in a top view, an aerial image of an EUV mask in the region of a defective imaging structure before and after an illustrative repair operation.

FIG. 3 gives a schematic illustration of a detail of a simulation construction of a repaired imaging structure and the adjacent structures thereof in an EUV mask, where the simulation construction simulates illustrative methods of the invention.

FIG. 4 gives a schematic illustration of a top view of the simulation construction of FIG. 3, especially the repaired structure and the adjacent structures thereof.

FIG. 5 illustrates simulated deviations of various critical dimensions from a predetermined critical dimension depending on the height of the repair material based on the simulation construction of FIG. 3 in EUV lithography.

FIG. 6 illustrates simulated deviations of critical dimensions from a predetermined critical dimension depending on the height of the repair material for various lateral extents of the repair material.

FIG. 7 illustrates simulated deviations of critical dimensions from a predetermined critical dimension depending on the height of the repair material in EUV lithography for various refractive indices and extinction coefficients of the simulated repair material.

FIG. 8 illustrates an atomic force micrograph and corresponding atomic force micrographs of depositions of repair material in different sizes in an illustrative method of the invention.

FIG. 9 shows an illustrative device of the invention.

### DETAILED DESCRIPTION

EUV masks may comprise, for example, (unwanted) defects. For example, a defect may be caused in the production of the EUV mask. In addition, a defect may also be caused by (lithographic) processing of the EUV mask, a process deviation in (lithographic) processing, transport of the EUV mask, etc. On account of the usually costly and complex production of an EUV mask, the defects are therefore usually repaired.

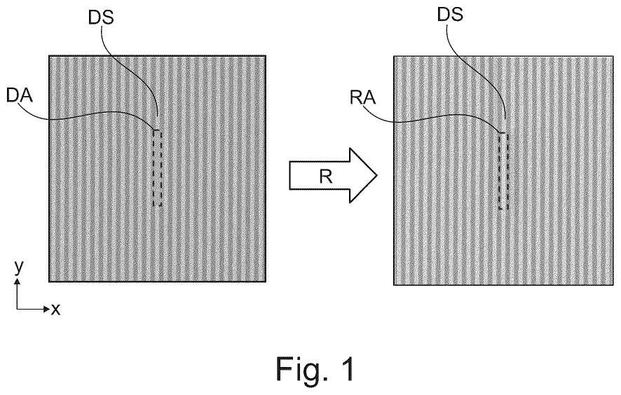

FIG. 1 illustrates, in a top view, scanning electron micrographs of an EUV mask in the region of a defective imaging structure before and after an illustrative repair operation in a method of the first aspect of the invention. The left-hand image in FIG. 1 shows an image before a repair operation. What can be seen here is a defect detail comprising a defective structure DS. The defective structure DS is faulty since it should constitute a continuous line according to the mask design, as apparent in the adjacent structures. However, the structure DS lacks material in the defect region DA. The defective structure DS is thus not a continuous line. The defect region DA may cause defects in the optical imaging of the mask in the course of EUV lithography. This defect may propagate to the lithographically produced structures and lead, for example, to faulty semiconductor chips. It is therefore customary to remedy or to repair mask defects. In the example of FIG. 1, repair material was deposited in the defect region DA via a repair operation R. The result of the repair operation is illustrated in the right-hand image in FIG. 1. The now repaired defective structure DS is thus apparent here by the repair region RA. By virtue of the deposited repair material in the repair region RA, the repaired defective structure DS constitutes a line as defined by the mask design. By virtue of the repair operation R, the optical properties in the repair region RA may correspond essentially to the optical properties at a different faultless site on the imaging structure as well. The repair operation R can thus at least minimize or even eliminate a mask fault which is reflected in the optical image in the course of EUV lithography.

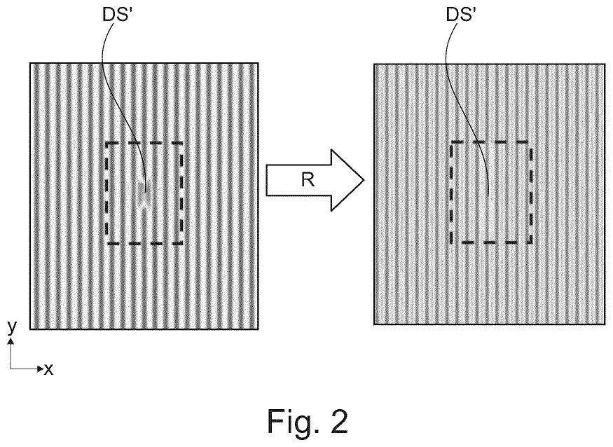

The effect of a repair operation on the optical image of the EUV mask is shown by way of example in FIG. 2.

Thus, FIG. 2 illustrates, in a top view, an aerial image of an EUV mask in the region of a defective imaging structure before and after an illustrative repair operation R. The aerial image may correspond, for example, to an optical image of the EUV mask that would also exist in the case of exposure in the EUV lithography itself. For example, the aerial image may correspond to the optical image of the EUV mask with the optical wavelength of the EUV lithography method, which may typically be in the region of 13.5 nm. The aerial image may correspond, for example, to the optical image of the EUV mask in a reference plane which is subjected to EUV lithography (for example a wafer plane, a photoresist plane, etc.). Typically, an aerial image of an EUV mask can be derived or determined by a measurement with an appropriate mask analysis system (for example via a mask inspection system, a mask microscope etc.). The aerial image may constitute, for example, the intensity progression of the radiation in EUV lithography in the reference plane. The aerial image may be used, for example, for determination of the optical quality of the EUV lithography and/or of the EUV mask.

The aerial image can be determined, for example, for various focal planes of EUV lithography.

The left-hand image in FIG. 2 shows an aerial image in which there is an image of the defective structure DS′. In this example, the defective structure in the defect region thereof is lacking its layer material at least to some degree. The defective structure thus comprises a clear defect (as described herein). The target structuring of the EUV mask corresponds, in the detail of FIG. 2, to a linear progression of the imaging structures. What can be seen in the left-hand image in FIG. 2, however, is that the image of the defective structure DS' by comparison with the progression of the aerial image of the surrounding regions constitutes a significant local deviation. For instance, the intensity progression is greatly altered around the image of the defective structure DS′, which means that the homogeneous linear progression of the aerial image is interrupted. If this defective structure were to be imaged in EUV lithography, a correspondingly faulty structure would be imaged, for example, on a wafer. However, this can be prevented via a mask repair as likewise shown in FIG. 2. For instance, it is possible via a repair operation R to reduce the faulty optical deviation in the defect region of the defective structure, as apparent in the right-hand image in FIG. 2. The repair operation R was effected (as in FIG. 1) via deposition of repair material in the defect region of the defective structure. It can be seen that the visual progression around the image of the defective structure DS' then corresponds essentially to the uniform progression of the surrounding regions of the aerial image. By use of a suitable repair, it is thus possible to ensure that no relevant faults are imaged in the EUV lithography.

It should be mentioned that the critical dimensions (described herein) can be read off from the aerial image. In other words, the critical dimensions may typically be based on the aerial image (or the optical image of the EUV mask). For example, it may be known that an imaging structure has an essentially radiation-absorbing design. Accordingly, for example, regions in the aerial image with a low intensity can be assigned to an imaging structure. Accordingly, for example, regions in the aerial image with a high or relatively high intensity can be assigned to a region of the EUV mask in which there is no imaging structure. For example, it is possible to read off the edges (described herein) from the aerial image for determination of the corresponding critical dimension. It is thus possible to read off the line CDs and the interspace CDs of the optical image in EUV lithography from the aerial image.

As mentioned herein, the critical dimensions (described herein) can also be taken from a wafer print (for example analogously, as detailed for an aerial image).

Details are given hereinafter as to how the repair operations described herein can be used in accordance with the invention to optimize the critical dimension in a region around a defective structure. This can be demonstrated, for example, by simulation results.

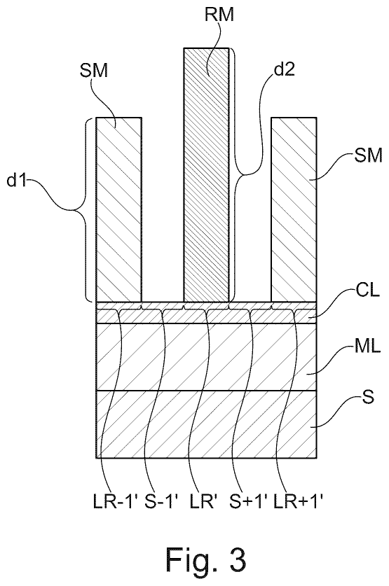

FIG. 3 gives a schematic illustration of a detail of a simulation construction of a repaired imaging structure and the adjacent structures thereof in an EUV mask, where the simulation construction simulates illustrative methods of the invention. The simulation construction shows the cross section of the simulated EUV mask. The EUV mask comprises a substrate S and an adjoining reflective layer stack ML. The substrate may comprise silicon for example. The reflective layer stack ML may comprise two or more layers, such that reflection of EUV radiation can be caused at the reflective layer stack ML. An outer layer CL may adjoin the reflective layer stack ML. The outer layer CL may comprise ruthenium for example (for example, the outer layer CL may be formed essentially from ruthenium).

FIG. 3 shows three structures by way of example on the outer layer CL. Firstly, two faultless imaging structures of the EUV mask are shown, formed from a layer material SM. The height of the faultless imaging structures is indicated by a target height d1. Also shown is a repair material RM. The repair material RM is provided in a defective region of a defective structure, where the layer material of the imaging structure is completely absent in the defective region. The repair material RM thus replaces the missing material of the defective imaging structure in the region shown. The height of the repair material is indicated by the repair material height d2. The lateral extent of the repair material RM is indicated by the repair material width LR′. The repair material width LR′ thus corresponds to the width of the repair material on the EUV mask. The lateral extent of the two adjacent imaging structures is indicated by the structure width LR−1′ and the structure width LR+1′. The structure widths LR−1′, LR+1′ thus correspond to the width of the faultless imaging structures on the EUV mask.

Also shown in FIG. 3 is the respective distance between the repair material RM and the adjacent faultless structures. Firstly indicated is the distance S+1′ of the EUV mask, which indicates the distance between repair material RM and the adjacent faultless structure to the right in FIG. 3. Also indicated is the distance S−1′ of the EUV mask, which indicates the distance between repair material RM and the adjacent faultless structure to the left in FIG. 3.

In the simulation construction, corresponding optical properties may be chosen for the respective layers and/or materials. For example, for the layer material SM and/or the repair material RM, a corresponding refractive index (for example a real part and/or an imaginary part of a complex refractive index) may be established. It is likewise possible, for example, to establish a corresponding extinction coefficient for the layer material SM and/or the repair material RM. In the simulation, the properties of the layer material SM were chosen such that these correspond to a ruthenium-tantalum compound. Thus, for the layer material SM, a refractive index of n=0.9153 and an extinction coefficient of k=0.0292 were chosen. The properties of the repair material RM were firstly chosen such that these correspond to a chromium-oxygen compound (CrₓO_{y}). For example, this was achieved by an appropriate selection of the refractive index and/or extinction coefficient for the repair material RM.

In addition, the geometries of the layers and/or materials may be varied in the simulation in order to examine corresponding dependences in a repair operation. In the simulation, the target height d1 of the layer material was set as a constant and the repair material height d2 was varied.

The simulation was effected such that the simulation construction of the EUV mask was subjected to simulated EUV irradiation. The simulation may be based, for example, on a rigorous numerical simulation. The simulation may take account, for example, of the complex interaction of various effects, for example diffraction, reflection, radiation absorption, phase shifting, etc. For example, the simulation may also include various parameters from EUV lithography (for example focal plane, focus, dose, illumination optics, angle of incidence, etc.). Proceeding from this complex interaction, the aerial image of the simulated EUV mask can be determined in a reference plane. The simulation described herein can be effected, for example, by use of the Dr.LiTHO software.

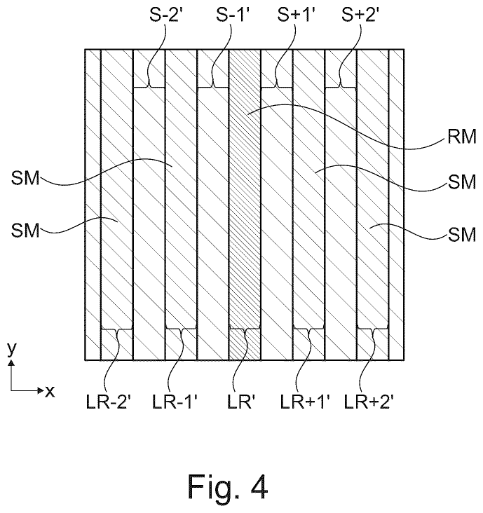

FIG. 4 gives a schematic illustration of a top view of the simulation construction of FIG. 3, especially the repaired structure and the adjacent structures thereof. What is thus shown is the repair material width LR′, which corresponds to the width of the repair material RM of the repaired structure. It is also possible to infer the structure widths of the adjacent faultless structures that are based on the layer material SM and the target height d1. The structure widths of the adjacent structures are correspondingly indicated as LR+1′, LR−1′, LR+2′, LR−2′. In addition, the distances from the repair material RM to the directly adjacent structures from the layer material are indicated as S−1′ and S+1′. Furthermore, the distances between the other structures are also indicated as S−2′ and S+2′.

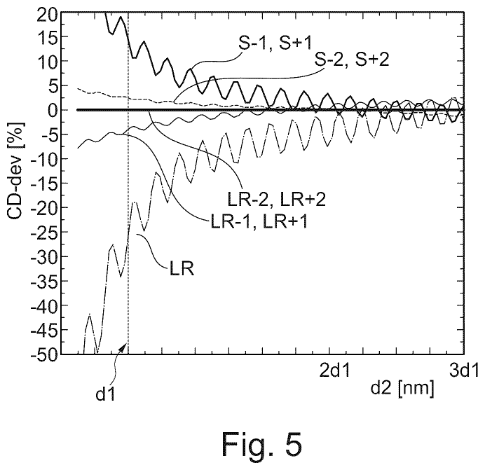

FIG. 5 illustrates simulated deviations of various critical dimensions from a predetermined critical dimension depending on the height of the CrₓO_{y} repair material based on the simulation construction of FIG. 3 in EUV lithography.

The simulated deviation is indicated here as CD-dev in percent. A measure is thus enabled here for the deviation of a critical dimension from the corresponding predetermined critical dimension. The predetermined critical dimension may correspond, for example, to an ideal target dimension (or target value) that would exist if there were no defective region. For example, it is possible to determine the target dimension from a simulation in which there are only faultless structures in the simulation construction. In this ideal case, the line CDs and/or interspace CDs of structure images may correspond to the corresponding target dimension. In addition, the target dimension used may also be a corresponding specification value of a critical dimension which is reported for the simulated EUV mask by a manufacturer (for example for particular EUV parameters).

In FIG. 5, it is possible to infer the line CDs and interspace CDs of the simulated optical image. The line CD LR may be based on an optical image of the repaired structure with the repair material width LR′. For example, the line CD LR may be inferred from the intensity progression of the optical image, which corresponds to the optical image of the repaired structure with the repair material width LR′. The same may apply correspondingly to the other line CDs or interspace CDs. For example, it is possible to generate an aerial image from the simulation construction of FIG. 3, from which the corresponding line CDs and interspace CDs can be read off.

FIG. 5 can show by way of example the effect of the height of the repair material height on the line CDs and interspace CDs.

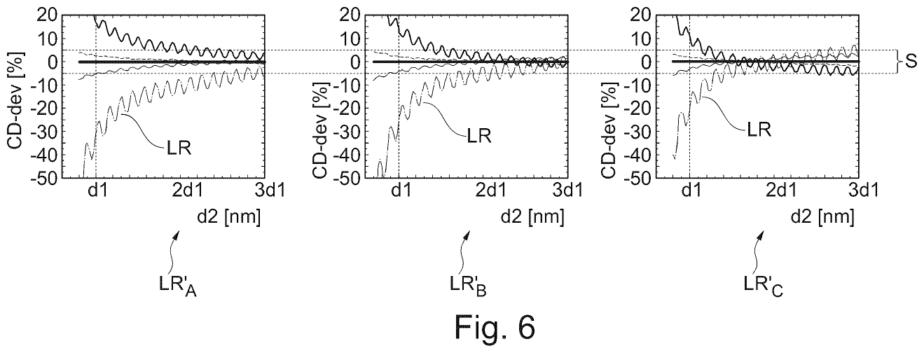

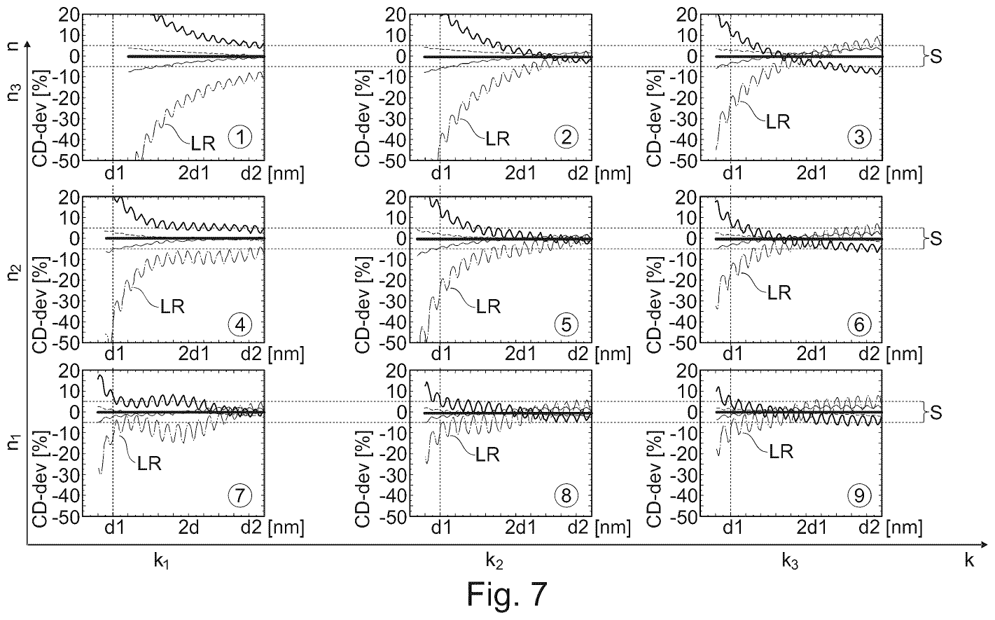

FIG. 5 shows the repair material height d2 is shown on the x axis. It can be seen that, as the repair material height d2 increases, the deviation of the line CD LR can be reduced. In addition, periodic fluctuations in the line CD LR are apparent. These are attributable to interference phenomena resulting from the optical image. For instance, the effect of the EUV wavelength of 13.5 nm can be inferred from the interference phenomenon. Also marked in FIG. 5 is the target height d1 of the faultless structures of the simulation. It can thus be inferred that, with an excessive height of the repair material RM relative to the target height d1, the deviation of the line CD LR can be reduced reliably. The maximum excess height in FIG. 5 is about 300% (d2=3d1), in which case the deviation of the line CD LR is virtually zero neglecting the interference phenomena. With the excess height of the repair material RM relative to the target height d1 of a faultless ruthenium-tantalum structure, it is thus also possible, for example, with a chromium-oxygen compound (CrₓO_{y}) to achieve a significant reduction in the deviation of the line CD LR (and also of the further critical dimensions). Further effects and characteristics on optical quality in the scope of the repair method described herein are discussed with regard to FIGS. 6 and 7.

In addition, FIG. 5 also shows the interspace CD S−1 and the interspace CD S+1 (of the optical image). It is also apparent here that, as repair material height d2 increases, the deviation of the interspace CD S−1 and the interspace CD S+1 from the target value thereof decreases.

It is likewise possible to read off the deviations of the line CD LR−1 and the line CD LR+1 (of the optical image). It is apparent here that the deviation thereof in the case of low repair material heights d2 is lower than the line CD LR. The repair material RM may thus also have an influence on the line CD which is based on structures adjoining the repaired structure. The repair material height affects not only the line CD LR (in accordance with the image of the repaired structure) but also the line CD LR−1 and line CD LR+1 (in accordance with the images of the structures adjacent to the repaired structure). However, this effect may be smaller than the effect on the line CD LR itself, which is influenced the most strongly by the repair material height. But there is likewise an apparent trend that, as the repair material height d2 increases, the deviation of the line CD LR−1 and the line CD LR+1 from the target value thereof can be reduced.

In addition, the progression of the interspace CD S−2 and of the interspace CD S+2 can be inferred. It is apparent that, as the repair material height d2 increases, the deviation of the interspace CD S−2 and of the interspace CD S+2 from the target value thereof decreases, with a smaller deviation than in the case of the interspace CD S−1 and S+1.

In addition, the progression of the line CD LR−2 and of the line CD LR+2 is also shown. The line CD LR−2 and the line CD LR+2 do not show any significant deviation in the critical dimension or any influence by the repair material height d2.

It should be mentioned that, for a discussion of illustrative methods of the invention with reference to the simulation results, the line CD LR based on the imaging of the repaired structure may be sufficient. It can be inferred from FIG. 5 (and also from the further simulation results indicated) that the deviation of the line CD LR is at its greatest in terms of the trend. It can thus be assumed that, if the line CD LR meets sufficient conditions, the other critical dimensions will not have any greater deviation either. Discussion hereinafter will therefore concern exclusively the curve progression of the line CD LR, which is also marked, for example, in the further graphs in FIGS. 6 and 7.

FIG. 6 illustrates the simulated deviation of the critical dimension for various line CDs and interspace CDs as a function of height of the CrₓO_{y} repair material for various lateral extents. This involved variation of the repair material width LR′ in the simulation construction of the EUV mask and determination of the corresponding deviation of the line CD LR for various repair material heights d2. The middle image of FIG. 6 shows the curve progression of the line CD LR, where the repair material width LR′B in this case also corresponded to the structure width of faultless structures of the simulation construction (i.e.: LR′_{B}=LR′−1=LR′+1). The left-hand image of FIG. 6 shows the curve progression of the line CD LR, where the repair material width LR′A chosen in this case was 3 nm narrower than the structure width of faultless structures of the simulation construction (i.e.: LR′_{A}+3 nm=LR′−1=LR′+1). The right-hand image of FIG. 6 here shows the curve progression of the line CD LR, where the repair material width LR′c chosen in this case was 3 nm wider than the structure width of faultless structures of the simulation construction (i.e.: LR′_{C}−3 nm=LR′−1=LR′+1).

It can be seen that, as the repair material width LR′ increases, the deviation of the line CD LR (for the same repair material height d2) decreases. FIG. 6 includes an illustrative specification range S that permits a deviation of the critical dimensions of +/−5 percent. Given the narrow repair material width of LR′_{A}, the specification range S can be achieved over and above a repair material height d2 of about 3·d1. Given the repair material width of LR′_{B} (i.e., the width of a faultless structure), the specification range S can be achieved over and above a repair material height of d2=2.4·d1. Given the highest repair material width of LR′_{C}, the specification range S can be achieved over and above a repair material height of d2=1.4·d1. With an increase in repair material width LR′, it is thus possible to further reduce the deviation of the line CD LR (and also of the further critical dimensions described herein). In addition, given a higher repair material width LR′, it is possible to use a lower repair material height d2, while nevertheless being able to assure optical quality (for example a particular deviation in the line CD LR) in the region of the repair site. The adjustment of the repair material width LR′ (or of the lateral extent of the repair material) thus constitutes a lever by which the quality of the repair can be crucially influenced.

In some examples, it is therefore possible to increase the width of the repair material LR′c (with parameters as described herein), where the height of the repair material is increased by not more than 20 nm and/or not more than 10 nm and/or not more than 20% and/or not more than 10% compared to the target height of the structure.

Secondly, there was also an examination of the influence that the focal plane in EUV lithography can have on deviation of the critical dimensions. Simulations were thus conducted in which the focal plane was defocused once by −2000 nm and once by +2000 nm. This was compared with a simulation in which there was an ideal focal plane and hence no defocusing. It was not possible here to observe any significant deviations in the critical dimensions as a function of the defocusing. The repairing of an EUV mask having ruthenium-containing imaging structures with the repair material mentioned herein can thus assure optical quality even in the case of fluctuations in focus during EUV lithography.

It should be mentioned that the simulation results so far are based on a repair material formed from a chromium-oxygen compound, but the corresponding mechanisms can also be applied in respect of all repair materials described herein.

FIG. 7 illustrates the simulated deviation of the critical dimension for various line CDs and interspace CDs as a function of the height of the repair material in EUV lithography for various refractive indices and extinction coefficients of simulated repair materials, the optical properties of which go beyond those of a chromium-oxygen compound. Plotted on the x axis are the three extinction coefficients k1, k2, k3 used, where k1<k2<k3. Shown on the y axis are the three refractive indices n1, n2, n3 used, where n1<n2<n3. The refractive indices n1, n2, n3 correspond to the real part of the complex refractive index of the repair material. The extinction coefficients k1, k2, k3 correspond to the imaginary part of the complex refractive index of the repair material. For each pair of an extinction coefficient and a refractive index, the corresponding simulation results are plotted. In FIG. 7, the simulation results are numbered 1-9, where the simulation results 1, for example, are based on a repair material for which a refractive index of n3 and an extinction coefficient of k1 have been established, etc. Additionally shown in the simulation results is a specification range S which (as was the case in FIG. 6) permits a deviation in the critical dimensions (described herein) of +/−5 percent.

There is an apparent trend in FIG. 7 that, as the extinction coefficient increases, deviations in the critical dimensions can be reduced. Thus, it can be inferred that, for higher extinction coefficients k (with the same refractive index n), for example, lower repair material heights d2 are needed to attain the specification range.

There is likewise an apparent trend in FIG. 7 that, as the refractive index decreases, deviation in the critical dimensions can be reduced. Thus, it can be inferred that, for lower refractive indices n (with the same extinction coefficient k), for example, lower repair material heights d2 are necessary to attain the specification range.

These two trends may be combined, for example, in the repair method described herein. For example, it is possible to configure the repair material via the method described herein such that it comprises a low refractive index n and a comparatively high extinction coefficient k. By use of the method described herein, it is possible, for example, to enable a repair material having a refractive index n from a range as described herein. In addition, it is possible to enable a repair material having an extinction coefficient k from a range as described herein.

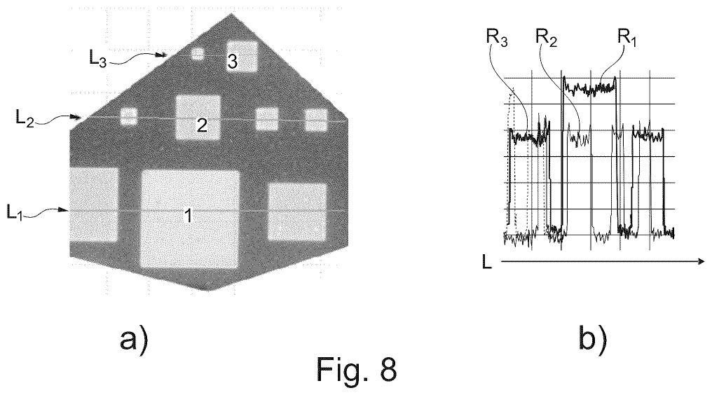

FIG. 8 illustrates an atomic force micrograph and corresponding atomic force micrographs of depositions of repair material in different sizes in an illustrative method of the invention. The left-hand image in FIG. 8 shows depositions of the same repair material, but merely with different dimensions of the repair material. Thus, the area of the deposition 1 is greater than the area of the deposition 2, where the area of the deposition 2 is greater than the area of the deposition 3. FIG. 8 can illustrate the morphology of the deposition over a wide size range. Thus, it should be noted that the roughness of the depositions is largely substrate-related and does not automatically depend on the deposition. For example, in the case of phase-shift EUV masks having a low surface roughness, for example, it is accordingly possible to ensure a repair material having a low surface roughness.

The left-hand image in FIG. 8 shows the gridlines L1, L2, L3 that were used for an atomic force micrograph. The corresponding micrographs are shown in the right-hand image of FIG. 8. Micrograph R1 corresponds to the atomic force micrograph along gridline L1. Micrograph R2 corresponds to the atomic force micrograph along gridline L2. Micrograph R3 corresponds to the atomic force micrograph along gridline L3. It can be seen that, firstly, the depositions 1, 2, 3 are of variable height, which may be caused by the different areas in the deposition. It is also apparent that surface roughness in depositions 1, 2, 3 does not have any significant mutual variation.

It should also be mentioned that the precursor gas (described herein) in the particle beam-induced deposition of the repair material may comprise at least one of the following: triruthenium dodecacarbonyl, bis(ethylcyclopentadienyl)ruthenium(II), ruthenocene, ruthenium pentacarbonyl, allylruthenium(II) tricarbonyl bromide, allylruthenium(II) tricarbonyl chloride, ruthenium tetracarbonyl iodide, ruthenium(III) nitrosyl chloride monohydrate.

In one example, the precursor gas (described herein) in the particle beam-induced deposition of the repair material may comprise at least one of the following: tetrarhodium dodecacarbonyl, rhodium carbonyl chloride, di-eta-chloro-tetrakis(phosphorus trifluoride)dirhodium.

In one example, it is also conceivable that two or more precursor gases may be used in the particle beam-induced deposition. It is possible here for each of the two or more precursor gases also to include, for example, one or more additive gases, in order to enable suitable deposition of the repair material.

In one example, several layers of repair material are deposited in one sequence. It is possible here, for example, for each layer to be deposited separately with a separate set of process parameters (as described herein). For example, a first layer of the repair material may be deposited with a first precursor gas. A second layer of the repair material may then be deposited, for example, with a second precursor gas, where the second precursor gas is different from the first precursor gas. In addition, it is also conceivable that different additive gases are used for different layers of the repair material.

Additionally or alternatively to the steps of the method described herein, it is also possible to add one or more auxiliary gases/auxiliary precursors alternately to the deposition processes as cleaning steps on the previously deposited repair material. For example, the deposition (of the first layer) of the repair material may be followed by a cleaning step, where at least one of the precursor gases described herein and/or one of the additive gases described herein is used.

In summary, by means of the methods described herein, a repair of a phase-shift EUV mask is thus possible. This invention can enable this, for example, by the three mechanisms that follow (as also already described herein).

Firstly, it is possible to use a repair material essentially identical to the material construction of the imaging structures. It is also conceivable that the layer structure of the imaging structures is essentially “rebuilt” in a defective region in the course of repair. If the imaging structure thus comprises three layers (composed of two or more different materials, for example), these layers or the material construction thereof may be replicated via an appropriate particle beam-induced deposition. In this example, the lateral extent of the repair material may be chosen such that it is identical to a reference structure within the scope of the specification. In addition, the height of the repair material may be adjusted to that of the surrounding faultless structures within the scope of the specifications.

In addition, it is possible to use a repair material having essentially the same optical properties of the system of the EUV mask (for example, the repair material may have essentially an n and k corresponding to the n and k of an imaging structure). In that case, for example, the lateral extent of the repair material may be chosen such that it is identical to a reference structure within the scope of the specification after the repair. In addition, the height of the repair material may be adjusted here to that of the surrounding faultless structures within the scope of the specifications.

Moreover, it is also possible to use a repair material that differs from the optical properties of the imaging structures or materials thereof. In that case, the lateral extent of the repair material and the height of the repair material may be chosen such that the repaired region of the mask effectively has the same optical properties (within the scope of the specification) as a corresponding faultless reference structure. The reference structure described herein may comprise, for example, a faultless imaging structure.

The method of the first aspect as described herein may be executed via the device of the invention described herein. In one example, the device comprises a mask repair device for repair or processing of lithography masks. The device may be used to localize and to repair or remedy mask defects. The device may comprise parts such as the device described in US 2020/0103751 A1 (see the corresponding FIG. 3A therein). The device may comprise, for example, a control unit which may, for example, be part of a computer system. The device, in one example, may be configured such that the computer system and/or the control unit controls the process parameters of the method in the first aspect as disclosed herein. This configuration can enable controlled, i.e., including automated, implementation of the method according to the invention as specified herein, for example without manual interventions. This configuration of the device can be achieved or enabled, for example, via the computer program according to the invention as described herein.

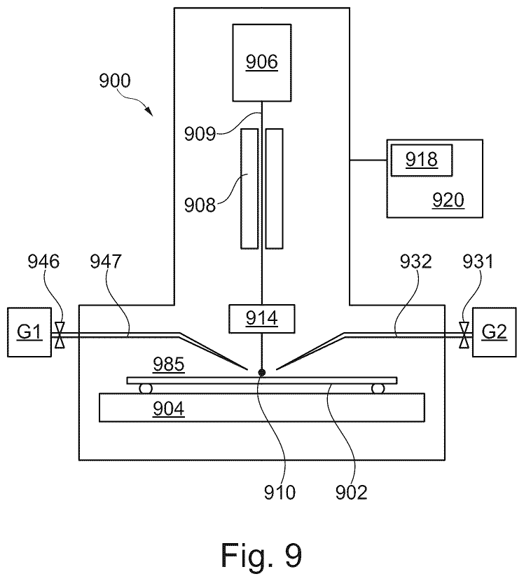

FIG. 9 shows a schematic section of an illustrative device 900 according to the invention. The device 900 may be configured such that it can perform a method in the first aspect of the invention. In one example, the device 900 of FIG. 9 comprises a mask repair device for repair or processing of lithography masks. The device 900 may be used to localize and to repair or remedy mask defects.

The illustrative device 900 of FIG. 9 may comprise, for example, a scanning electron microscope (SEM) for provision of a particle beam, which, in this example, is an electron beam 909. An electron gun 906 can generate the electron beam 909, which can be directed by one or more beam-forming elements 908 as a focused electron beam 910 onto a lithography mask 902, which is arranged on a sample stage 904 (or chuck). In addition, the scanning electron microscope can be used to control parameters/properties of the electron beam (e.g., acceleration voltage, dwell time, current, focusing, spot size, etc.) The parameters of the electron beam may be adjusted, for example, in relation to a parameter space of the methods described herein. The electron beam 909 may serve as an energy source for initiating a local chemical reaction in a working region of the lithography mask 902. This may be utilized, for example, for the methods described herein (for example, for the implementation of the electron beam-induced etching in the first aspect). In addition, the electron beam 909 may be utilized for imaging of the lithography mask 902. The device 900 may comprise here one or more detectors 914 for detecting electrons (for example secondary electrons, backscattered electrons).

In order to conduct the method described herein, the illustrative device 900 of FIG. 9 may include at least two reservoir vessels for at least two different processing gases or precursor gases. The first reservoir vessel G1 can store the precursor gas for example. The second reservoir vessel G2 can store the additive gas for example. In some examples, the temperatures of reservoir vessels G1 and G2 may be controlled independently of one another. In addition, in the illustrative device 900, each reservoir vessel G1, G2 has its own gas inlet system 932, 947, which can end with a nozzle close to the point of incidence of the electron beam 910 on the lithography mask 902. It is possible for each reservoir vessel G1, G2 to have its own control valve 946, 931 in order to control the amount of the corresponding gas provided per unit time, i.e., the gas flow rate of the corresponding gas. This can be effected in such a way that the gas volume flow rate is controlled at the point of incidence of the electron beam 910. In addition, the device 900, in one example, may include further reservoir vessels for additional gases that can be added to the method in the first aspect as one or more (additive) gases (e.g., oxidizing agent, reducing agent, halides as described herein). In addition, the device 900, in one example, may include further reservoir vessels for additional gases that can be added to the method in the first aspect as one or more precursor gases (for example, as described herein). The device 900 in FIG. 9 may include a pump system for generating and maintaining a pressure required in the process chamber 985.

The device 900 may also comprise a (closed-loop) control unit 918 which may, for example, be part of a computer system 920. The device 900, in one example, may be configured such that the computer system 920 and/or the control unit 918 controls the process parameters of the methods disclosed herein. This configuration can enable controlled or automated implementation of the methods according to the invention as specified herein, for example without manual interventions. This configuration of the device 900 can be achieved or enabled, for example, via the computer program according to the invention as described herein. The computer program in the third aspect as described herein may be stored in the computer system.

Further examples of the invention are described below:
1. Method of processing a phase-shift mask for EUV lithography, comprising:
   particle beam-induced depositing of a repair material (RM) using a precursor gas for repair of an imaging structure (DS) of the mask;
   wherein the imaging structure (DS) is repaired in such a way that at least one critical dimension (LR) of the mask has a deviation from a predetermined critical dimension of at least below 15%, preferably below 10%, more preferably below 5%, most preferably below 3%.
2. Method according to Example 1, wherein the at least one critical dimension (LR) comprises a lateral extent of an optical and/or lithographic image of the repaired structure of the mask.
3. Method according to Example 2, wherein the optical image is created by an EUV lithography system and/or with a mask examination system for EUV lithography.
4. Method according to Example 2 or 3, wherein the optical image comprises an aerial image of the mask.
5. Method according to any of Examples 1-4, wherein the at least one critical dimension comprises a lateral extent of an optical and/or lithographic image of an imaging structure adjacent to the repaired structure; and/or
   wherein the at least one critical dimension comprises a distance in an optical and/or lithographic image of the mask that comprises a distance between the image of the repaired structure and the image of an adjacent structure.
6. Method according to any of Examples 2-5, wherein the deviation from the predetermined critical dimension in two or more focal planes of the optical and/or lithographic image is below 15%, preferably below 10%, more preferably below 5%, most preferably below 3%.
7. Method according to any of Examples 1-6, wherein a real part of a complex refractive index of the imaging structure is between 0.88 and 0.99; and/or wherein an imaginary part of the complex refractive index of the imaging structure is between 0.005 and 0.08.
8. Method according to any of Examples 1-7, wherein the imaging structure comprises ruthenium.
9. Method according to any of Examples 1-8, wherein the precursor gas comprises ruthenium.
10. Method according to Example 9, wherein the precursor gas comprises a metal carbonyl comprising ruthenium.
11. Method according to Example 9 or 10, wherein the precursor gas comprises at least one of the following:
   triruthenium dodecacarbonyl, bis(ethylcyclopentadienyl)ruthenium(II), ruthenocene, ruthenium pentacarbonyl, allylruthenium(II) tricarbonyl bromide, allylruthenium(II) tricarbonyl chloride, ruthenium tetracarbonyl iodide, ruthenium(III) nitrosylchloride monohydrate, dichlorotricarbonylruthenium(II) dimer, hexaammineruthenium(III) chloride, benzeneruthenium(II) chloride, dimer, carbonylchlorohydridotris(triphenylphosphine)ruthenium(II), tetrakis(dimethylsulfoxide)dichlororuthenium(II), ruthenium(III) nitrosylnitrate, ruthenium(III) nitrosylsulfate, ruthenium(III) nitrosylacetate, ruthenium (VIII) oxide, tris(2,2′-bipyridyl)ruthenium(II) chloride, chloropentaammineruthenium(III) chloride, ruthenium(III) acetylacetonate, tetraamminechlorohydroxyruthenium(III) chloride, ruthenium(III) chloride, ruthenium(III) bromide, dichlorotris(triphenylphosphine)ruthenium(II), dihydrotetrakis(triphenylphosphine)ruthenium(II), (hexamethylbenzene)ruthenium(II) dichloride, dimer, chloro(cyclopentadienyl)bis(triphenylphosphine)ruthenium(II), ruthenium (IV) sulfide, chloro(4,4′-dicarboxy-2,2′-bipyridine) (p-cymene)ruthenium(II) chloride.
12. Method according to any of Examples 1-11, wherein the repair material (RM) comprises ruthenium.
13. Method according to any of Examples 1-12, wherein the particle beam-induced depositing of the repair material (RM) is also effected with use of an additive gas.
14. Method according to any of Examples 1-13, wherein a deviation of a real part of a complex refractive index of the repair material (RM) from a real part of a complex refractive index of the imaging structure is less than 7%, preferably less than 5%, more preferably less than 3%, most preferably less than 2%.
15. Method according to any of Examples 1-14, wherein a complex refractive index of the repair material (RM) has an imaginary part β such that a deviation of the value 1−β from the value 1−βr is less than 5%, preferably less than 4%, more preferably less than 3%, most preferably less than 2%, where βr is an imaginary part of a complex refractive index of the imaging structure.
16. Method according to any of Examples 1-15, wherein a real part of a complex refractive index of the repair material (RM) comprises a value within a range between 0.88 and 0.99, preferably between 0.88 and 0.96, more preferably between 0.88 and 0.92.
17. Method according to any of Examples 1-16, wherein an imaginary part of a complex refractive index of the repair material (RM) comprises a value within a range between 0.005 and 0.08, preferably between 0.01 and 0.06, more preferably between 0.01 and 0.04.
18. Method according to any of Examples 1-17, wherein the precursor gas comprises rhodium.
19. Method according to Example 18, wherein the precursor gas comprises a metal carbonyl comprising rhodium.
20. Method according to Example 18 or 19, wherein the precursor gas comprises at least one of the following:
   tetrarhodium dodecacarbonyl, rhodium carbonyl chloride, di-eta-chloro-tetrakis(phosphorus trifluoride)dirhodium, hexarhodium hexadecacarbonyl, rhodium octanoate dimer, rhodium(III) trifluoroacetylacetonate, rhodium(III) nitrate anhydrous, dirhodium(II) tetrakis(caprolactam), acetylacetonatobis(ethylene)rhodium(I), chlorobis(ethylene)rhodium(I) dimer, rhodium(II) acetate dimer, rhodium(III) chloride trihydrate, hydridotetrakis(triphenylphosphine)rhodium(I), dicarbonyl(2,4-pentanedionato)rhodium(I), rhodium(III) oxide (anhydrous), rhodium(III) acetate, rhodium(II) trifluoroacetate dimer, tetrakis(1,5-cyclooctadiene)tetra-μ-hydridotetrarhodium, pentaamminechlororhodium(III) dichloride.
21. Method according to any of Examples 18-20, wherein the repair material comprises rhodium.
22. Method according to any of Examples 1-21, wherein the precursor gas comprises chromium.
23. Method according to Example 22, wherein the precursor gas comprises a metal carbonyl comprising chromium.
24. Method according to any of Examples 1-23, wherein the particle beam-induced depositing is effected in such a way that a height (d2) of the repair material (RM) is greater than a target height (d1) of the structure, where the target height (d1) of the structure corresponds to a height of the structure at a non-faulty site.
25. Method according to any of Examples 1-24, wherein a height (d2) of the repair material (RM) comprises a height of not more than 300%, not more than 180%, not more than 150%, not more than 120%, or not more than 110% of a target height (d1) of the structure.
26. Method according to any of Examples 1-25, wherein a difference of a height (d2) of the repair material (RM) from a target height (d2) on the structure corresponds to a value within a range from 0 nm to 150 nm, 0 nm to 30 nm, o nm to 20 nm, 0 nm to 10 nm, or 0 nm to 5 nm.
27. Method according to any of Examples 24-26, wherein the target height of the structure corresponds to a value within a range from 10 nm to 100 nm, 10 nm to 80 nm or 10 nm to 70 nm.
28. Method according to any of Examples 1-27, wherein the particle beam-induced depositing is effected in such a way that a lateral extent (LR′) of the repair material is different from a lateral target extent of the structure, wherein the lateral target extent of the structure corresponds to a lateral extent of the structure at a non-faulty site of the structure.
29. Method according to Example 28, wherein the lateral extent of the repair material comprises a value that varies from the lateral target extent of the structure by not more than 80%, not more than 50%, not more than 30%, or not more than 10%.
30. Method according to Example 28 or 29, wherein the lateral target extent of the structure is lower than 300 nm, preferably lower than 200 nm, more preferably lower than 100 nm, most preferably lower than 80 nm.
31. Phase-shift mask for EUV lithography that has an imaging structure, wherein the imaging structure has been repaired via particle beam-induced deposition of a repair material (RM) using a precursor gas; wherein, as a result of the repair to the imaging structure (DS), at least one critical dimension (LR) of the mask has a deviation from a predetermined critical dimension of at least below 15%, preferably below 10%, more preferably below 5%, most preferably below 3%.
32. Mask according to Example 31, wherein the at least one critical dimension (LR) comprises a lateral extent of an optical and/or lithographic image of the repaired structure of the mask.
33. Mask according to Example 31 or 32, wherein the mask has been processed by a method according to any of Examples 1-30.
34. Computer program comprising instructions which, when executed by a computer system, cause the computer system to perform a method according to any of Examples 1-30.
35. Device (900) for processing a mask for EUV lithography, comprising:
   means for particle beam-induced depositing of a repair material using a precursor gas for repair of an imaging structure of the mask;
   a computer system comprising the computer program according to Example 34.

What is claimed is:

1. A method of processing a phase-shift mask for EUV lithography, comprising:
determining a repair site on the mask where an imaging structure of the mask is considered to be faulty;
determining at least one reference site on the mask where an imaging structure of the mask is considered not to be faulty; and
particle beam-induced depositing of a repair material at the repair site using a precursor gas;
wherein the particle beam-induced depositing is effected such that a height at the repair site is greater than a height at the at least one reference site.

2. The method of claim 1, wherein the reference site is determined in such a way that the height at the reference site is assumed to be essentially the same as at the repair site if the repair site were not faulty.

3. The method of claim 1, wherein the reference site is determined in such a way that the reference site and the repair site should have the same height in relation to a specification of the mask.

4. The method of claim 1, wherein the repair site and the reference site adjoin one another.

5. The method of claim 1, wherein the repair site and the reference site are spatially separate from one another.

6. The method of claim 1, wherein, in relation to a construction of the mask, the repair site and the reference site would lie on the same imaging structure if the repair site were not faulty.

7. The method of claim 1, wherein, in relation to a construction of the mask, the repair site lies on a first imaging structure, and the reference site lies on a second imaging structure;
wherein the first imaging structure and the second imaging structure are different.

8. The method of claim 1, wherein the imaging structure is repaired in such a way that at least one critical dimension of the mask has a deviation from a predetermined critical dimension of at least below 15%.

9. The method of claim 8, wherein the at least one critical dimension comprises a lateral extent of an optical and/or lithographic image of the repaired structure of the mask.

10. The method of claim 9, wherein the optical image is created by an EUV lithography system and/or with a mask examination system for EUV lithography.

11. The method of claim 9, wherein the optical image comprises an aerial image of the mask.

12. The method of claim 8, wherein the at least one critical dimension comprises a lateral extent of an optical and/or lithographic image of an imaging structure adjacent to the repaired structure; and/or
wherein the at least one critical dimension comprises a distance in an optical and/or lithographic image of the mask that comprises a distance between the image of the repaired structure and the image of an adjacent structure.

13. The method of claim 9, wherein the deviation from the predetermined critical dimension in two or more focal planes of the optical and/or lithographic image is below 15%.

14. The method of claim 1, wherein a real part of a complex refractive index of an imaging structure of the mask is between 0.88 and 0.99; and/or wherein an imaginary part of the complex refractive index of an imaging structure of the mask is between 0.005 and 0.08.

15. The method of claim 1, wherein an imaging structure of the mask comprises ruthenium.

16. The method of claim 1, wherein the precursor gas comprises ruthenium.

17. The method of claim 16, wherein the precursor gas comprises a metal carbonyl comprising ruthenium.

18. The method of claim 16, wherein the precursor gas comprises at least one of the following:
triruthenium dodecacarbonyl, bis(ethylcyclopentadienyl)ruthenium(II), ruthenocene, ruthenium pentacarbonyl, allylruthenium(II) tricarbonyl bromide, allylruthenium(II) tricarbonyl chloride, ruthenium tetracarbonyl iodide, ruthenium(III) nitrosylchloride monohydrate, dichlorotricarbonylruthenium(II) dimer, hexaammineruthenium(III) chloride, benzeneruthenium(II) chloride, dimer, carbonylchlorohydridotris(triphenylphosphine)ruthenium(II), tetrakis(dimethylsulfoxide)dichlororuthenium(II), ruthenium(III) nitrosylnitrate, ruthenium(III) nitrosylsulfate, ruthenium(III) nitrosylacetate, ruthenium (VIII) oxide, tris(2,2′-bipyridyl)ruthenium(II) chloride, chloropentaammineruthenium(III) chloride, ruthenium(III) acetylacetonate, tetraamminechlorohydroxyruthenium(III) chloride, ruthenium(III) chloride, ruthenium(III) bromide, dichlorotris(triphenylphosphine)ruthenium(II), dihydrotetrakis(triphenylphosphine)ruthenium(II), (hexamethylbenzene)ruthenium(II) dichloride, dimer, chloro(cyclopentadienyl)bis(triphenylphosphine)ruthenium(II), ruthenium (IV) sulfide, or chloro(4,4′-dicarboxy-2,2′-bipyridine) (p-cymene)ruthenium(II) chloride.

19. The method of claim 1, wherein the repair material comprises ruthenium.

20. The method of claim 1, wherein the particle beam-induced depositing of the repair material is also effected with use of an additive gas.

21. The method of claim 1, wherein a deviation of a real part of a complex refractive index of the repair material from a real part of a complex refractive index of an imaging structure of the mask is less than 7%.

22. The method of claim 1, wherein a complex refractive index of the repair material has an imaginary part β such that a deviation of the value 1−β from the value 1−βᵣ is less than 5%, where βᵣ is an imaginary part of a complex refractive index of an imaging structure of the mask.

23. The method of claim 1, wherein a real part of a complex refractive index of the repair material comprises a value within a range between 0.88 and 0.99.

24. The method of claim 1, wherein an imaginary part of a complex refractive index of the repair material comprises a value within a range between 0.005 and 0.08.

25. The method of claim 1, wherein the precursor gas comprises rhodium.

26. The method of claim 25, wherein the precursor gas comprises a metal carbonyl comprising rhodium.

27. The method of claim 25, wherein the precursor gas comprises at least one of the following:
tetrarhodium dodecacarbonyl, rhodium carbonyl chloride, di-eta-chloro-tetrakis(phosphorus trifluoride)dirhodium, hexarhodium hexadecacarbonyl, rhodium octanoate dimer, rhodium(III) trifluoroacetylacetonate, rhodium(III) nitrate anhydrous, dirhodium(II) tetrakis(caprolactam), acetylacetonatobis(ethylene)rhodium(I), chlorobis(ethylene)rhodium(I) dimer, rhodium(II) acetate dimer, rhodium(III) chloride trihydrate, hydridotetrakis(triphenylphosphine)rhodium(I), dicarbonyl(2,4-pentanedionato)rhodium(I), rhodium(III) oxide (anhydrous), rhodium(III) acetate, rhodium(II) trifluoroacetate dimer, tetrakis(1,5-cyclooctadiene)tetra-μ-hydridotetrarhodium, or pentaamminechlororhodium(III) dichloride.

28. The method of claim 25, wherein the repair material comprises rhodium.

29. The method of claim 1, wherein the precursor gas comprises chromium.

30. The method of claim 29, wherein the precursor gas comprises a metal carbonyl comprising chromium.

31. The method of claim 1, wherein the particle beam-induced depositing is effected in such a way that the height at the repair site is greater than a predetermined target height of the imaging structure to be repaired, wherein the predetermined target height corresponds to a height of the imaging structure to be repaired at a non-faulty site corresponding to the reference site.

32. The method of claim 1, wherein the height at the repair site comprises a height of not more than 300% of the height at the reference site.

33. The method of claim 1, wherein a difference of the height at the repair site from the height at the reference site corresponds to a value within a range from 0 nm to 150 nm.

34. The method of claim 1, wherein the height at the reference site corresponds to a value within a range from 10 nm to 100 nm.

35. The method of claim 1, wherein the particle beam-induced depositing is effected in such a way that a lateral extent of the repair material is different from a lateral target extent of the structure, wherein the lateral target extent of the structure corresponds to a lateral extent of the structure at a non-faulty site of the structure.

36. The method of claim 35, wherein the lateral extent of the repair material comprises a value that varies from the lateral target extent of the structure by not more than 80%.

37. The method of claim 35, wherein the lateral target extent of the structure is lower than 300 nm.

38. A phase-shift mask for EUV lithography, wherein an imaging structure of the mask at a repair site has been repaired via particle beam-induced deposition of a repair material using a precursor gas;
wherein a height at the repair site is greater than a height at at least one reference site on the mask where an imaging structure of the mask is considered not to be faulty, wherein at the reference site no particle beam induced deposition was effected.

39. The mask of claim 38, wherein the mask has been processed by a method according to claim 1.

40. A computer program comprising instructions which, when executed by a computer system, cause the computer system to perform a method according to claim 1.

41. A device for processing a mask for EUV lithography, comprising:
means of particle beam-induced deposition of a repair material using a precursor gas for repair of an imaging structure of the mask; and
a computer system comprising the computer program according to claim 40.
